(19) United States
(12) Patent Application Publication
(10) Pub. No.: US 2024/0032262 A1
(43) Pub. Date: Jan. 25, 2024

(54) COOLING ENCLOSURE FOR VARIABLE FREQUENCY DRIVE

(71) Applicant: North American Electric, Inc., Hernando, MS (US)

(72) Inventor: Richard Alan Cornutt, Southaven, MS (US)

(73) Assignee: North American Electric, Inc., Hernando, MS (US)

(21) Appl. No.: 18/372,012

(22) Filed: Sep. 22, 2023

Related U.S. Application Data
(63) Continuation-in-part of application No. 17/182,225, filed on Feb. 22, 2021, now abandoned.
(60) Provisional application No. 62/979,689, filed on Feb. 21, 2020.

(51) Int. Cl. H05K 7/20

(52) U.S. Cl. CPC H05K 7/20909

(57) ABSTRACT

An apparatus for cooling a variable frequency drive (VFD) is disclosed including an enclosure having a first portion isolated from a second portion, the first portion defining a space configured to house one or more internal components. The second portion defines a compartment, an ingress in communication with the compartment for facilitating entry of air into the compartment, and an egress for facilitating an exit of the entered air from the compartment. Air flowing from the ingress to the egress is configured to pass over one or more heat sinks of the VFD to dissipate heat from the VFD.

### CROSS REFERENCE TO RELATED APPLICATIONS

This application claims priority to U.S. patent application Ser. No. 17/182,225, titled “Vortex Cooling Tunnel in Variable Frequency Drive”, filed Feb. 22, 2021, which claims priority to U.S. Provisional Patent Application Ser. No. 62/979,689, titled “Vortex Cooling Tunnel (VCT)”, filed Feb. 21, 2020. The entirety of these applications are expressly incorporated by reference herein.

### FIELD OF THE INVENTION

The present invention is generally directed towards an enclosure for a variable frequency drive (VFD) and more specifically towards an enclosure for cooling a VFD.

### BACKGROUND OF THE INVENTION

Variable frequency drives (VFDs) are typically used to adjust the frequency of an electric motor such that the electric motor can function at variable frequencies. However, the operation of a VFD may cause it to heat up because of both internal and environmental factors. Traditional methods for cooling VFDs include: (a) incorporating a “push through” design, (b) forced air cooling using external fans, (c) air conditioning, and/or (d) isolation of the VFD and other internal components in an environmentally controlled space (e-house).

High frequency power electronics used to create pulse-width modulation (PWM) wave forms in VFDs create heat which must be constantly managed to prevent overheating of the VFDs electronic components and in the case of a VFD apparatus, overheating of other panel mounted components. The installation and environmental factors must be considered along with external sources of heat, that is, either they should be removed or managed appropriately. For instance, an important external consideration may be the effect of direct sunlight in which, practical precautions should be taken to remove the harmful effects by providing adequate shelter to the VFD.

Below is an explanation of sample calculations required for adequate ventilation/cooling of a traditional VFD apparatus. These calculations are described for illustration purposes and do not take into consideration external factors, such as direct sunlight or additional heat sources.

The first step in heat management of a traditional VFD apparatus is to calculate how much heat the equipment inside the VFD apparatus generates. This is dependent on the type of equipment and how it is configured and operated. To calculate VFD Heat Dissipation, the thermal losses of the VFD may, for all practical purposes, be assumed to be about 3%. The thermal losses for smaller VFDs may be assumed to be approximately 4% and as the size of the VFD increases, the percentage of thermal losses decreases to about 3%. For the purposes of below explanations, the above general rules are considered.

In an exemplary scenario, the estimated heat generated by a 40 Ampere VFD controlling a 22 Kilowatt electric motor at full load is:

$$\begin{matrix}{P}_{LOSS} = 22 kW \times 0.03 \\ = 0.66 kW \\ = 660 W\end{matrix}$$

Another consideration in these calculations may be the auxiliary equipment. Where additional equipment is mounted in the same enclosure as the VFD, any heat generated by such auxiliary equipment must be added to the total heat generated. Equipment suppliers may provide details of the heat generated by their equipment(s).

Further, various installation alternatives may also need to be considered. VFDs are available from VFD manufacturers sealed to different levels to suit the environment in which they need to be installed. The level of sealing determines the level of protection offered against water and objects, known as an Ingress Protection (IP) rating. If the protection offered is not adequate for the environment into which it is to be installed, then other alternatives need to be investigated. One alternative is to relocate the VFD equipment to an alternative location/position. However, such relocation may not always be a feasible option given certain design constraints.

If the factory IP rating of the VFD equipment is not sufficient for the application, another alternative is to install the VFD equipment in an enclosure that can provide the appropriate IP rating for the application. The disadvantage with this alternative is that when the VFD equipment, which generates heat, is installed into another enclosure, the heat must be dissipated or cooled. If this heat is not removed, the heat inside the VFD apparatus will build up to a level which will affect the reliable operation of the VFD, reduce the life expectancy of the VFD, and/or cause failure to other equipment inside the enclosure. There are several traditional methods used to prevent, dissipate, or cool the heat generated by the VFD that may build up inside the enclosure.

One method incorporates a “push through” design when mounting the VFD in the enclosure. This alternative locates the heat sinks outside the enclosure envelope by cutting a hole in the side or back of the enclosure which therefore isolates the heat from the sensitive controls. This gives the overall assembly a higher thermal rating, implying that the VFD can survive in higher ambient climates. However, disadvantages of this design include exposure of the cooling fans and heat sink to the environment, which may cause premature fan failure or degraded heat dissipation, thereby, causing premature faults and ultimately, failure of the VFD. Also, consideration must be taken to ensure that the IP rating of the enclosure is not reduced due to the hole that is cut in the enclosure to allow the heat sink to be pushed through to the outside of the enclosure, therefore placing the electrical components inside the enclosure at risk.

Another method of addressing the heat generated by the VFD is to install the VFD in a non-ventilated enclosure. Non-ventilated enclosures rely on the heat to be dissipated through the walls of the enclosure. Better heat conduction of the enclosure leads to more dissipation of heat. Therefore, metal enclosures are better at dissipating heat than plastic enclosures. The dimensions of the enclosure, how it is mounted, and the outside ambient temperature defines the amount of heat that can be dissipated through the exposed surfaces of the enclosure. The power that can be dissipated in a given exposed surface area is given by the expression below:

P_{ESA}=k×S×ΔT, where:
P_{ESA}: Power dissipated from within the enclosure via exposed surface area in Watts (W)
k: Heat transfer coefficient (sheet metal˜5.5 W/m2K, plastic˜3.5 W/m2K)
S: Corrected enclosure surface area of the enclosure, in m 2 in accordance with IEC890.
ΔT: Temperature differential (inside enclosure−outside ambient), in ° C.

Due to the high amount of heat typically generate by a VFD, mounting a VFD in a traditional, non-ventilated enclosure is rarely a viable option.

In situations where the surface area of the enclosure is insufficient to dissipate the heat generated inside the enclosure, the remaining or residual heat may be removed by forced ventilation. With a ventilated enclosure using force ventilation, the heat is dissipated by forcing ambient air in or out of the enclosure by mounting additional fans and/or vents in the enclosure. The objective here is to circulate the air through the enclosure. Generally, ambient air is drawn in near the bottom of the enclosure and discharged through a ventilation opening near the top of the enclosure. Air filters are usually installed on fan units and over additional vents to prevent dust and dirt from being pulled into the enclosure with the ambient air. The type of air filter determines the level of filtration, but most traditional enclosure air filters allow small amounts of dust to enter the enclosure which, over time, can harm the electrical components inside. Additionally, as the filter collects any dust, the airflow will be reduced significantly and must be considered in the selection decision and design. The volume of air required may be estimated using the formula:

V=(3.1×P_{EXHAUST})/ΔT, where—
V: Volume of air flow required, in m3/hr
P_{EXHAUST}: Power exhausted from within the enclosure, in W
ΔT: Temperature differential (inside enclosure−outside ambient), in ° C.

The additional fans that must be installed to provide the required cooling for forced ventilation consume additional electricity which reduces the overall energy efficiency of the VFD apparatus. In addition to this, the air filters require regular maintenance to prevent them from clogging and reducing the required air flow to cool the enclosure and the equipment inside which increases the overall cost of operation. In general, the use of forced ventilation can create many undesirable results.

Air conditioning is required to cool the VFD apparatus when the environment requires that the enclosure remain totally sealed to prevent any dust or water from entering the enclosure. This type of application is common when the enclosure is subjected to extremely dusty environments where fans with air filters cannot be feasibly used, or environments that require hose directed water for cleanup purposes as in food processing facilities. It is also a common choice if the ambient temperature of the environment exceeds the operational parameters of the equipment inside the enclosure. A specialized air conditioning unit is installed in a hole cut into the enclosure, and the air conditioning unit is sized to cool the heat being generated by the VFD and other components inside the enclosure. The use of an air conditioning unit adds to the initial cost of the VFD apparatus and requires ongoing maintenance to keep it operating properly. The air conditioning unit must run whenever the VFD is in operation, so the additional consumption of electricity for operation makes it the least energy efficient and least desirable of all cooling methods, and is normally used only as a last resort.

Another traditional method for cooling enclosed VFDs is installing them in an S-house. This method involves installing the VFD inside a much larger structure, or house, that is fully enclosed and then air conditioned by conventional air conditioning units. This method is normally used when many VFDs are being required in a single facility to operate machines that are installed in close proximity to each other, such as in an industrial setting. This method is not economically feasible when one or only a few VFDs are required in one area.

Further, there may be additional considerations in the design and selection of best method/system as described below:

Equipment Spacing—To adequately exhaust the generated heat, certain minimum clearances must be maintained around the VFD. The VFD installation manual may be referred to for details on specification of the VFD.

Equipment/Stirring fans—Stirring fans distribute the heat evenly throughout the enclosure to avoid hot spots. Fans may be controlled to run for a given time at starting or temperature may be controlled to extend fan life and reduce audible noise.

Forced Ventilation—Where ventilation is used to exhaust heat, care should be taken with regard to IP rating of the enclosure. Furthermore, the size of the air intake should be at least the size of the exit and if more than one fan is used then the fans should be the same. Where filters are used, pressure drops across the filters should be taken into consideration. Filters should be inspected regularly for blockage as part of the maintenance schedule to ensure free air flow and correct operation. Force ventilation may also be temperature controlled to minimize running time and increase the life expectancy of the fans.

Equipment Derating—The components of electronic equipment are designed to operate under full load at a particular maximum temperature. By reducing the load, the internal operating temperature may be reduced allowing the equipment to operate in a higher ambient temperature. The instruction manual or the local representative may be referred to for manufacture derating. Derating can significantly increase the cost of the overall product.

Solar Heating—Exposure of the enclosure to the sunlight (direct or reflected) may result in solar heating. Proper use of a shelter may reduce such heating. The enclosure material and paint colors have different absorption properties of solar energy. Traditional VFD packages and bare VFD chassis should not be mounted in direct sunlight or on hot surfaces.

As noted above, traditional enclosures and methods for cooling VFDs face several challenges and require consideration of numerous factors, and there is no single method that provides all of the characteristics customers may desire in a VFD apparatus.

### SUMMARY OF THE INVENTION

The VFD apparatus, in accordance with the embodiments of this disclosure, isolates the watt loss from the internal components of the drive package and, therefore, removes the heat from the internal components and eliminates the need for external cooling. This results in the VFD cooling itself (i.e., no external fans, filters, or air conditioning equipment is required) and eliminates contaminants from getting inside the enclosure where the electrical components are located.

According to some aspects of the present disclosure, a variable frequency drive (VFD) apparatus includes an enclosure including a first portion and a second portion, wherein the first portion is isolated from the second portion by an internal wall, one or more internal components coupled with the internal wall and at least partially housed in a space defined by the first portion of the enclosure, and a compartment defined by the second portion of the enclosure, wherein the second portion further defines an ingress and an egress, the ingress defined in communication with the compartment and configured to direct air from outside of the enclosure into the compartment, wherein heat from the one or more internal components is dissipated by the air, and heated air is directed out of the compartment through the egress, and further wherein the heated air moving toward the egress and the air directed into the compartment through the ingress are configured to generate a vortex region moving through the compartment.

According to some aspects of the present disclosure, a method of cooling a variable frequency drive (VFD), the method includes defining a space within an internal divider, wherein the space is configured to at least partially receive one or more electrical components and one or more heat sinks, positioning the internal divider within an enclosure to define a first portion of the enclosure and a second portion of the enclosure such that the first portion is isolated from the second portion by the internal divider, and positioning the one or more electrical components within the space of the internal divider such that the one or more electrical components are positioned within the first portion of the enclosure and the one or more heat sinks are positioned in the second portion of the enclosure. The method further includes facilitating an inflow of air from outside of the enclosure, through an ingress defined by an exterior wall of the second portion and into a compartment housed in the second portion of the enclosure, traversing the ambient air through the compartment, directing the air such that heat from the one or more heat sinks is dispersed by the air and at least part of the air becomes heated air, and facilitating an exit of the heated air through an egress defined at an upper portion of the second portion of the enclosure, wherein the air is isolated from one or more internal components housed in the first portion of the enclosure.

According to some aspects of the present disclosure, an apparatus for housing and cooling a VFD includes an enclosure including a first portion defining a space and a second portion defining a compartment, wherein the enclosure further includes an upper wall and a lower wall, an internal divider extending between the upper wall and lower wall of the enclosure and defining an opening, a VFD positioned within the opening of the internal divider, wherein a heat sink of the VFD is positioned within the compartment, a panel coupled with the VFD and further coupled with the internal divider, the panel including a gasket configured to seal the panel and the internal divider, wherein the first portion is isolated from the second portion by the internal divider and the panel, an ingress defined by the second portion of the enclosure and in communication with the compartment, and an egress defined by the second portion of the enclosure and in communication with the compartment, wherein the ingress and the egress are configured to direct air from external of the enclosure through the ingress, over the heat sink of the VFD, and outward of the enclosure through the egress.

These and other features, aspects, and advantages of the present disclosure will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

Further advantages of the invention will become apparent by reference to the detailed description of preferred embodiments when considered in conjunction with the drawings:

FIG. 1A is a front perspective view of a VFD apparatus with a front door in a closed position according to various examples.

FIG. 1B is a front perspective view of the VFD apparatus of FIG. 1A with the front door removed and including a VFD.

FIG. 1C is a front view of the VFD apparatus of FIG. 1B with the VFD removed.

FIG. 2 is a front view of the VFD apparatus of FIG. 1B.

FIG. 3 is a side cross-sectional view of the VFD apparatus of FIG. 2 taken along line III-III.

FIG. 4 is a top cross-sectional view of the VFD apparatus of FIG. 2 taken along line IV-IV with the VFD shown in block diagram.

FIG. 5 is a block-diagram of a VFD, according to various examples.

FIG. 6 is a front perspective view of a VFD apparatus with a door in a closed position, according to various examples.

FIG. 7 is a rear perspective view of the VFD apparatus of FIG. 6.

FIG. 8A is a front perspective view of the VFD apparatus of FIG. 6 with the door removed and including a VFD.

FIG. 8B is a front perspective view of the VFD apparatus of FIG. 8A with the VFD removed.

FIG. 9 is a rear perspective view of the VFD apparatus of FIG. 7 with a second portion of an enclosure removed.

FIG. 10 is a cross-sectional view of the VFD apparatus of FIG. 9 taken along line X-X.

FIG. 11 is a front perspective view of a second portion of an enclosure of the VFD apparatus of FIG. 6.

FIG. 12 is a front perspective exploded view of the second portion of FIG. 11.

FIG. 13 is a cross-sectional view of the VFD apparatus of FIG. 8B taken along line XIII-XIII.

FIG. 13A is an enlarged view of section A of FIG. 13.

FIG. 13B is an enlarged view of section B of FIG. 13.

FIG. 14 is a cross-sectional view of the VFD apparatus of FIG. 8B taken along line XIV-XIV.

FIG. 15 is a cross-sectional view of the VFD apparatus of FIG. 8A taken along line XV-XV.

FIG. 16 is a cross-sectional view of the VFD apparatus of FIG. 8A taken along line XVI-XVI.

FIG. 17 is an enlarged view of section XVII of the cross-sectional view of the VFD apparatus of FIG. 14.

Repeat use of reference characters in the present specification and drawings is intended to represent the same or analogous features or elements of the present disclosure.

### DETAILED DESCRIPTION OF INVENTION

Reference will now be made in detail to present embodiments of the invention, one or more examples of which are illustrated in the accompanying drawings. The detailed description uses numerical and letter designations to refer to features in the drawings. Like or similar designations in the drawings and description have been used to refer to like or similar parts of the invention.

As used herein, the terms “first,” “second,” and “third” may be used interchangeably to distinguish one component from another and are not intended to signify location or importance of the individual components. The terms “coupled,” “fixed,” “attached to,” and the like refer to both direct coupling, fixing, or attaching, as well as indirect coupling, fixing, or attaching through one or more intermediate components or features, unless otherwise specified herein.

The singular forms “a,” “an,” and “the” include plural references unless the context clearly dictates otherwise.

Approximating language, as used herein throughout the specification and claims, is applied to modify any quantitative representation that could permissibly vary without resulting in a change in the basic function to which it is related. Accordingly, a value modified by a term or terms, such as “about,” “approximately,” “generally,” and “substantially,” is not to be limited to the precise value specified. In at least some instances, the approximating language may correspond to the precision of an instrument for measuring the value, or the precision of the methods or apparatus for constructing or manufacturing the components and/or systems. For example, the approximating language may refer to being within a ten percent margin.

Moreover, the technology of the present application will be described with relation to exemplary embodiments. The word “exemplary” is used herein to mean “serving as an example, instance, or illustration.” Any embodiment described herein as “exemplary” is not necessarily to be construed as preferred or advantageous over other embodiments. Additionally, unless specifically identified otherwise, all embodiments described herein should be considered exemplary.

As used herein, the term “and/or,” when used in a list of two or more items, means that any one of the listed items can be employed by itself, or any combination of two or more of the listed items can be employed. For example, if a composition or assembly is described as containing components A, B, and/or C, the composition or assembly can contain A alone; B alone; C alone; A and B in combination; A and C in combination; B and C in combination; or A, B, and C in combination.

The following detailed description is presented to enable any person skilled in the art to make and use the invention. For purposes of explanation, specific details are set forth to provide a thorough understanding of the present invention. However, it will be apparent to one skilled in the art that these specific details are not required to practice the invention. Descriptions of specific applications are provided only as representative examples. Various modifications to the preferred embodiments will be readily apparent to one skilled in the art, and the general principles defined herein may be applied to other embodiments and applications without departing from the scope of the invention. The present invention is not intended to be limited to the embodiments shown but is to be accorded the widest possible scope consistent with the principles and features disclosed herein.

For the purposes of easier understanding, the term “enclosure” is used in this disclosure to describe a housing for a VFD that encloses all the internal parts of the VFD. Further, internal electronic components may not necessarily be limited to the components disclosed explicitly in this disclosure and may include any electronic component that may be required for the functioning of the VFD in accordance with the disclosed embodiments. Further, the apparatus disclosed in the following embodiments may not necessarily be of the same shape, size and cross-section as illustrated in the corresponding figures and may have any shape such as, but not limited to, spherical, cylindrical, cuboidal that may be either geometrically symmetrical or asymmetrical without departing from the scope of the ongoing description. Further, the apparatus may be partially or completely hollow or in some embodiments, may not be hollow at all but still is capable of being designed in a manner so as to isolate the internal circuitry from the air that enters the enclosure. Additionally, in various examples, the exhaust mechanism may comprise fans, slits, or vents or any other equivalent arrangement to expel air out of the VFD without departing from the scope of the ongoing disclosure.

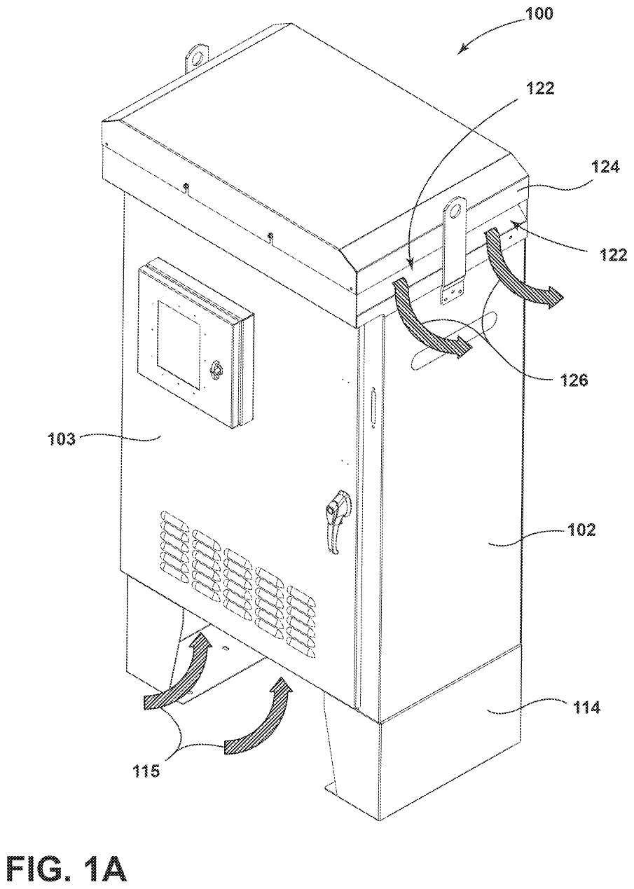

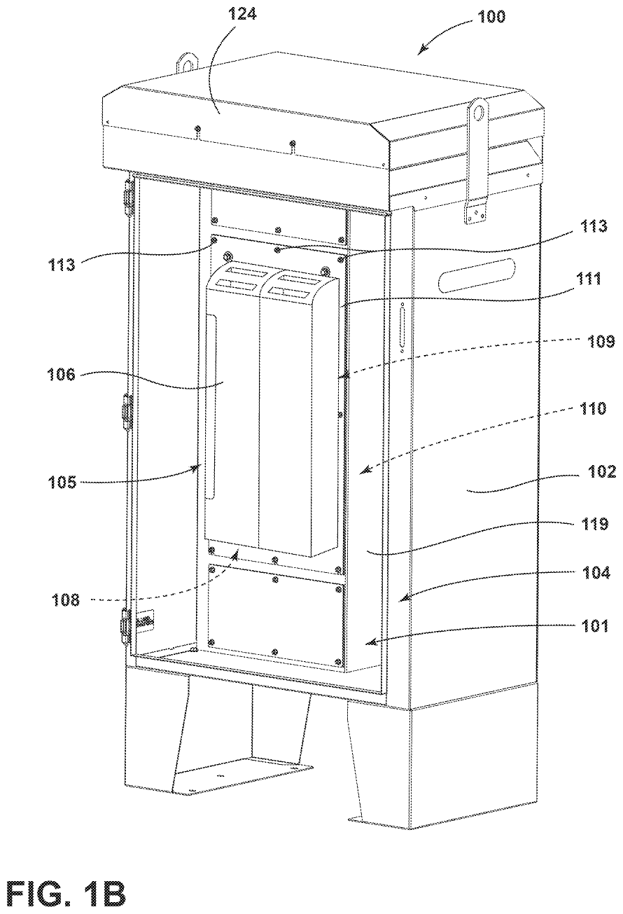

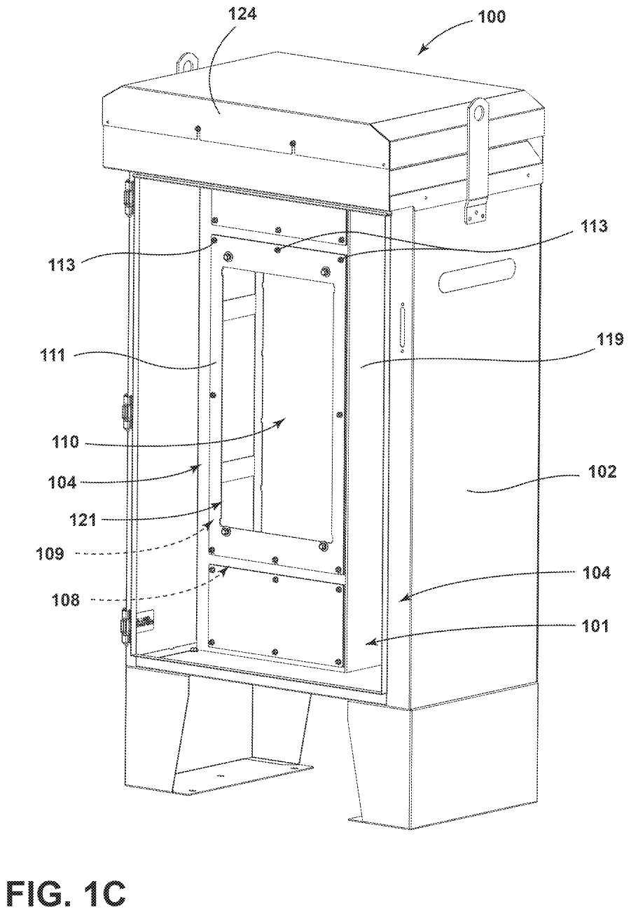

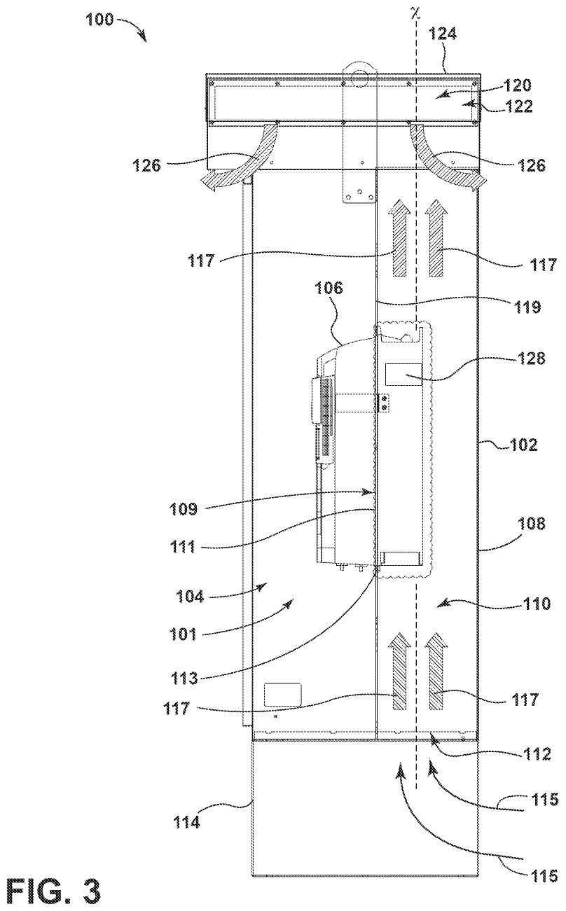

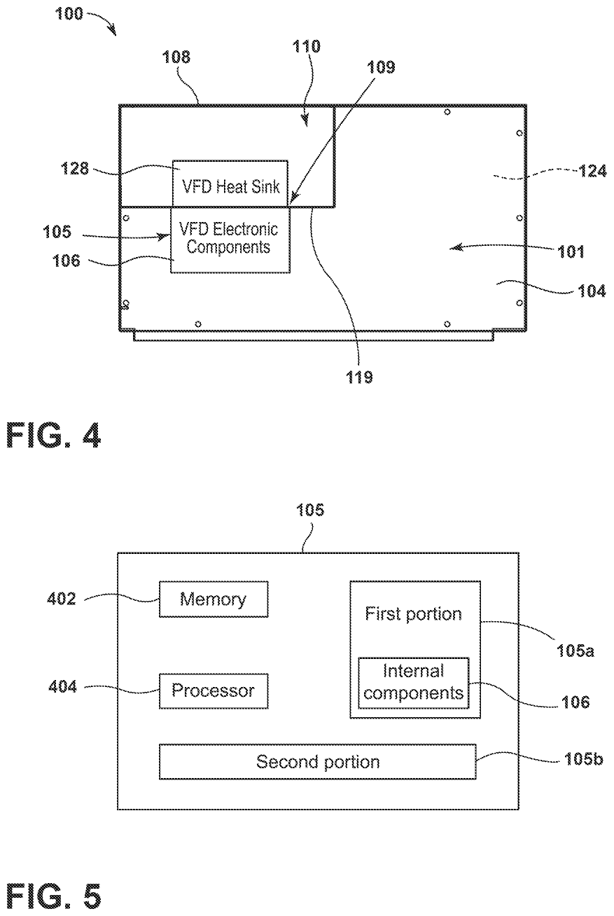

In view of the challenges of traditional VFD apparatuses as described above, the present disclosure proposes various examples of a variable frequency drive (VFD) apparatus 100. A first exemplary VFD apparatus 100 is shown in FIGS. 1A-5. As best shown in FIGS. 3-4, the VFD apparatus 100 is configured to allow the heat generated by heat sinks 128 of a VFD 105 during operation to be dispersed into the surrounding atmosphere by using only the VFD's integral cooling system, as designed and equipped by the VFD manufacturer, and without the use of any additional fans to assist with the removal and dissipation of the heat. As shown in the examples included herein, the VFD apparatus 100 includes an enclosure 102 having a first portion 104 and a second portion 108. A door 103 may be coupled with the enclosure 102 and configured to selectively close the enclosure 102 when in a closed position, as shown in FIG. 1A. The enclosure 102 of the VFD apparatus 100 is configured such that such that one or more internal electronic components 106 of a VFD 105, are housed in a space 101 defined by the first portion 104 of the enclosure 102. The one or more electronic components 106 may include circuitry between components along with the components themselves. Further, the VFD apparatus 100 includes a compartment 110 defined by the second portion 108 of the enclosure 102. The first and second portions 104, 108 of the enclosure 102 are separated and isolated by an internal divider 119 which may be a wall coupled with or integrally formed with the enclosure 102. In various examples, the VFD 105 may be positioned through an opening 109 defined in the internal divider 119 such that the electrical components 106 of the VFD 105 are positioned within the first portion 104 of the enclosure 102 and one or more heat sinks 128 of the VFD 105 are in the second portion 108 of the enclosure 102. The second portion 108 of the enclosure 102 defines an ingress 112 in communication with the compartment 110 and configured for facilitating entry of air into the compartment 110. The second portion 108 further defines an egress 120 in communication with the compartment 110 and configured for facilitating an exit of the air from the compartment 110. The second portion 108 may be configured to define the ingress 112 and the egress 120 such that a vortex region, referred to herein as a vortex cooling tunnel (VCT) is formed within the compartment 110 as the heated air moves from the ingress 112 to the egress 120. The second portion 108 may be further configured such that air moving from the ingress 112 to the egress 120 is directed to flow over the one or more heat sinks 128 of the VFD 105. In various examples, an exhaust mechanism 122 may be configured to facilitate the exit of the air flowing through the egress 120.

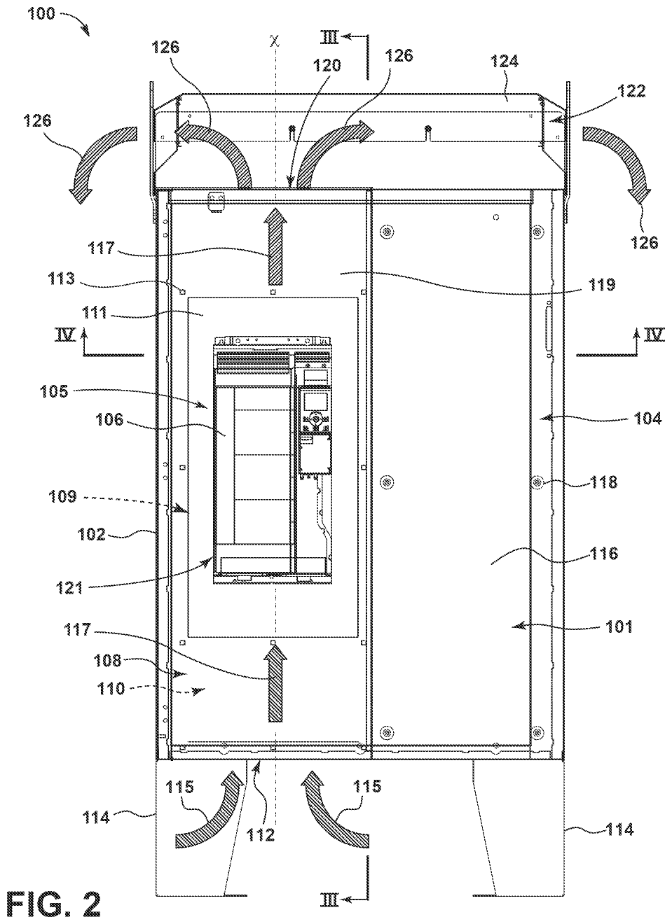

FIGS. 1A-2 illustrate a front view of a VFD apparatus 100 in accordance with various examples. The VFD apparatus 100 comprises an enclosure 102 having a first portion 104 and a second portion 108. The first portion 104 defines a space 101 configured to receive and house one or more internal electronic components 106 that are essential for the functioning of a VFD. These components 106 may include various electronic components such as, but not limited to, diodes, transistors, capacitors, resistors in any suitable combination depending on the design requirements of a VFD 105 housed by the enclosure 102.

As shown in FIGS. 1C-3, the second portion 108 of the enclosure 102 may define a compartment 110 for facilitating flow of air for cooling the VFD 105 in accordance with the embodiments of this disclosure. For instance, the compartment 110 of the second portion 108 may be configured as a cooling tunnel, which is herein referred to as a “vortex cooling tunnel” or “VCT”, that isolates heat generated from the watt loss from the internal electrical components 106 of the VFD 105 positioned within the space 101 defined by the first portion 104 of the enclosure 102. The cooling tunnel may be configured such that the airflow through the compartment 110 is achieved/facilitated in a manner similar to a vortex region as understood in the context of fluid dynamics. For instance, as best shown in FIGS. 2 and 3, the airflow velocity may be greatest next to an axis X of the cooling tunnel or compartment 110 and may decreases in inverse proportion to the distance from the axis X. For instance, the distribution of velocity and vorticity (i.e., the curl of the flow velocity), as well as the concept of circulation, may be used to characterize the airflow forming a vortex region through the cooling tunnel. The heat generated by electrical components 106 of the VFD 105 and transmitted to the heat sink(s) 128 of the VFD 105 along with the integral cooling system of the VFD 105 creates a vortex type condition that enhances the upward movement of the air through the compartment 110. However, the mere naming convention does not restrict any design changes to the VFD, the enclosure 102, the compartment 110, or any other features of the apparatus 100 that may be made according to the implementation requirements. It may be appreciated that various shapes, sizes, dimensions, and cross sections are envisaged which may or may not lead to vortex-like characteristics in the airflow through the cooling tunnel without departing from the scope of the ongoing disclosure.

The enclosure 102 is configured such that the first portion 104 of the enclosure 102 houses at least the one or more internal electronic components 106 of the VFD 105 and is isolated from the second portion 108 that defines the compartment 110. For example, the first portion 104 of the enclosure 102 may be separated and isolated from the second portion 108 of the enclosure and the compartment 110 defined therein by an internal divider 119. The internal divider 119 may be formed of one or more walls extending from a top wall of the enclosure 102 to a bottom wall of the enclosure 102. The internal divider 119 may be operably coupled with the enclosure 102 or integrally formed with the enclosure 102. For example, the internal divider 119 may be tack welded to the enclosure 102 to separate and isolate the first portion 104 of the enclosure 102 from the second portion 108 of the enclosure 102. This prevents the external air that enters the compartment 110 from exterior of the enclosure 102 through the ingress 112 of the compartment 110 from flowing through the isolated first portion 104 of the enclosure 102, thereby, protecting the components 106 from contaminants that may be present in the external air.

In various examples, the internal divider 119 may define an opening 109 configured to at least partially receive the VFD 105 such that the one or more heat sinks 128 of the VFD 105 are positioned within the second compartment 110 (see FIG. 3) and the internal electronic components 106 of the VFD 105 are positioned within the first compartment 104. As best shown in FIG. 1, a panel 111 may be coupled with the VDF 105 and may be coupled with the internal divider 119 to cover the opening 109. The panel 111 may be operably coupled with the internal divider 119 using fasteners 113.

Referring again to FIGS. 1C-3, the shape of the compartment 110 defined by the second portion 108 of the enclosure 102 may be a symmetrical geometric shape such as, but not limited to, a cuboidal, or a cylindrical shape. The cross-section of the compartment 110 defined by the second portion 108 may accordingly be circular, square, or rectangular or any other shape depending on the overall dimensions of the second portion 108 of the enclosure 102. In various examples, the dimensions of the second portion 108 and the compartment 110 may be varied within the design constraints of the enclosure 102. For example, the dimensions of the enclosure 102 may be about 60×36×24 (length×width×height) inches. The dimensions of the second portion 108 may accordingly be varied to define the compartment 110 within the enclosure 102 based on design considerations as described above. For example, one half of the volume available within the enclosure 102 may be designated for a cuboidal second portion 108 and compartment 110 having dimensions of about 30×18×12 inches. In this example, the first portion 104 may also house the internal circuitry and internal electronic components of the VFD 105 while the second portion 108 houses one or more heat sinks 128 of the VFD 105 while maintaining isolation of the one or more electronic components 106 from the air entering the VCT. In another example, the compartment 110 may be cylindrical with a diameter of about 12 inches and a height/length of about 30 inches. The remaining volume, in both these examples, inside the enclosure 102 may be used for other components such as, but not limited to, an exhaust mechanism 122.

As shown in FIGS. 1C and 2, the second portion 108 of the enclosure 102 may further define the ingress 112 through which external air enters the compartment 110 as shown by arrows 115. The air flowing along arrows 115 into the compartment 110 may include one or more foreign objects such as, but not limited to, dirt particles, moisture, insects and other contaminants. Such foreign objects are restricted from entering the first portion 104 of the enclosure 102 by isolation of the compartment 110 of the second portion 108 through which the external air flows, protecting the internal electronic components 106 and any associated circuitry of these components 106 for exposure to the foreign objects. This objective is achieved by isolating the compartment 110 from the first portion 104 of the enclosure 102 that houses these internal electronic components 106 and any associated circuitry.

One of the design features of the enclosure 102 presented in this disclosure is that it enables the VFD 105 to cool itself by dissipating heat through the heat sinks 128 and the air flow (see arrows 115, 117, and 126) through the compartment 110 of the second portion 108 of the enclosure 102. The enclosure 102 does not require any external blowers to cool the VFD, as using external blowers as often used in the prior art may have several disadvantages:
a. the mean time between failure (MTBF) for the drive package is greatly reduced due to fan failure times;
b. opening holes for ventilation may cause issues with the Underwriters Laboratories (UL) 508 standard conformity and most often reduces the desired IP rating;
c. push or pull fan configurations require filters which reduces the resulting air flows and degrades fan performance and lifecycle; and
d. bringing outside air into the enclosure invites contamination.

The present disclosure, therefore, proposes to develop a compartment or tunnel 110 (e.g., the VCT) inside the above-described enclosure 102 that allows air flow over one or more VFD heat sinks 128 of the VFD 105. This method isolates the heat and outside air from the inside space 101 of the first portion 104 of the enclosure 102 and critical electronic components 106. This upgrades the environmental rating, as discussed in more detail below, and extends the life of the VFD apparatus 100 improving the overall reliability in the process.

Further, for additional stability, the enclosure 102 may comprise an enclosure stand 114 that may include two or more legs to support the enclosure 102. The enclosure 102 may further comprise an outer covering that is attached to the enclosure 102 for example by means of fixtures which may comprise screws, nuts and bolts, or adhesives. The outer covering may provide additional safety from external shocks or environmental factors.

As shown in FIGS. 1A-2, once the air illustrated by arrows 115 enters the compartment 110 of the second portion 108 through the ingress 112, the air (as shown by arrows 115) flows through the compartment 110 in such a manner that the design of the compartment 110 and the enclosure 102 isolates it from entering the first portion 104 of the enclosure 102 and damaging the internal electronic components 106. The air then traverses through the compartment 110 housed in the second portion 108, as shown by arrows 117, and the heat generated from the internal components 106 during their operation is dissipated into the air (as shown by arrows 117) traversing through the compartment 110. Thus, the heat is not allowed to damage the components 106. In various examples, the air shown by arrows 117 flows over one or more heat sinks 128 in the enclosure 102 before exiting the compartment 110 through the egress 120.

The heated air shown by arrows 126 then exits the compartment 110 through the egress 120. In one example, the heat sinks 128 may be located at a predetermined distance that is close enough to the VCT egress 112 to efficiently evacuate the heat. In this example, the distance may be about 2 inches from the egress 120 of the second portion 108. The exit air flow shown by arrows 126 is best shown in FIGS. 2 and 3.

In various examples, an exhaust mechanism 122 in the enclosure 102 may facilitate the exit of the air out of the enclosure 102 as shown by arrows 126 after the air flows over the heat sinks 128 of the VFD 105. As discussed elsewhere herein, the distance of the exhaust mechanism 122 and the egress 120 may be about 2 inches from the heat sinks 128 of the VFD 105. However, this distance can vary depending on design requirements. In various examples, the exhaust mechanism 122 may be installed in a hood 124 of the enclosure 102. In other examples, the exhaust mechanism 122 may be installed on the sides of the hood 124 while, in some other embodiments, it may be installed on the top of the hood 124. In various examples, the exhaust mechanism 122 may comprise one or more exhaust fans, slits, or an equivalent arrangement suitable to evacuate the hot air exiting the egress 120 after flowing over the heat sinks 128 of the VFD 105 to outside of the enclosure 102.

Since the first portion 104 of the enclosure 102 (comprising the electronic components 106 and circuitry) is isolated from the second portion 108 (that comprises the VCT or the compartment 110) by the internal divider 119, the air that enters the compartment 110 does not come in contact with the electronic components 106. The air passes through the compartment 110 to flow over one or more heat sinks 128 that may be included in the second portion 108 of the enclosure 102 and subsequently, exits the enclosure 102 through the egress 120 of the second portion 108 and/or the exhaust mechanism 122. The disclosure does not limit the placement of the exhaust mechanism 122 in any manner. As previously discussed, in one exemplary instance, the exhaust mechanism 122 may comprise exhaust fans, slits, or vents that may be located on a hood (top) 124 of the enclosure while in another exemplary instance, the exhaust mechanism 122 may be located on one or more walls of the enclosure 102 (e.g., a front wall, a rear wall, or one or more side walls). In various examples, the location of the exhaust mechanism 122 on the side walls of the enclosure 102 may ensure better safety for a user. In other examples, the location of the exhaust mechanism 122 on the rear wall of the enclosure 102 may prevent water from entering the enclosure 102.

In accordance with the embodiments of the disclosure, a prototype was prepared and commercially named as “advanced tunnel design”. On testing the prototype, the following observations were concluded:
a) the shape and size of the tunnel make a significant difference in performance;
b) the construction of the tunnel was modified as described above to assist easing of routine maintenance;
c) the size and shape of the ingress is critical—not only to incoming air flow, but ingress of insects and other foreign objects as well; and
d) the placement of the intake/ingress is critical to optimize performance.

In view of the above observations, modifications were made to both the ingress 112 as described above and the egress 120 and/or the exhaust mechanism 122 compared to the conventional solutions available. For instance, in one scenario, the egress 120 and/or the exhaust mechanism 122 may be placed on top front portion of the enclosure 102. However, in other examples, in order to improve air flow, and for better safety, the egress 120 and/or the exhaust mechanism 122 may be positioned on the sides of the enclosure 102. Similarly, the position of the ingress 112 may be predetermined by the manufacturer and is not limited by the present disclosure. For example, the ingress 112 may be located either on one or more sides of the enclosure 102 or within the top (hood) 124 of the enclosure 102 depending on the design requirements and safety considerations. Additionally, the shape and size of the ingress 112 may be predetermined such that it is optimal to facilitate the inflow of air but restricts the inflow of insects or foreign contaminants. In one example the shape of the ingress 112 may be circular and the diameter may be about one-fourth of an inch. Additionally, a sieve or screen (not shown) may be installed on the ingress 112 to restrict the flow of contaminants into the VCT. On the contrary, the egress 120 may be relatively wider in diameter (for example, about 1 inch) to expel maximum air after the air flow has passed over the heat sinks 128.

The shape and size of the compartment 110 or VCT may be adapted to the characteristics of the VFD 105 installed, as described above. In one example, the shape of the compartment 110 may be cylindrical and the cross-sectional diameter may be about 12 inches with a height of about 30 inches. Further, the compartment 110 shape and size can be so designed such that the first and the second portions 104, 108 as described above are isolated and the air entering the compartment 110 does not enter and damage the internal electronic components 106 of the first portion 104. In some embodiments, the shape and size of the compartment 110 may be predetermined depending on the design requirements and to achieve the objective of isolating the first and the second portions 104, 108 of the VFD apparatus 100. In yet another example, the shape of the compartment 110 may be conical with the diameter decreasing along the axis from one end to the other.

Further, in an embodiment of the invention, access plates and/or a panel 111 may be configured to provide access to the cooling fans and heatsinks 128 of the VFD 105. Furthermore, mounting adapters (not shown) may be used to mount the VFD apparatus 100 on an external periphery such as a pole or onto a wall. In one example, the above-described design modifications may be such that the VFD 105 housed within the VFD apparatus 100 is able to achieve a variable torque, a voltage rating range of 240-480 volts, a horsepower of 200 HP and an Ampere rating of 250 Amperes. In another example, the horsepower range may be 1-700HP with other parameters remaining the same. While the overall dimensions of the VFD apparatus 100 in these examples may vary greatly, an exemplary embodiment of this example may be about 60×36×24 inches.

FIG. 4 illustrates a top view of the VFD apparatus 100 in accordance with the embodiments of this disclosure including the first and second portions 104, 108 and the space 101 and compartment 110 defined respectively therein, which allows the external air to traverse the compartment 110, that is, the VCT or vortex tunnel (as shown by arrows 117 in FIGS. 2-3) and subsequently, flow over the VFD heat sink 128, thus, providing a cooling mechanism to the VFD 105 without exposing any electrical components 106 of the VFD 105 to the external air flow. Then, as previously discussed and shown in FIGS. 1 and 2, the air exits through the egress 120 and/or the exhaust mechanism 122, which may be provided in the hood 124 of the enclosure 102.

FIG. 5 shows a basic illustration of the VFD 105 as discussed above in accordance with the embodiments of this disclosure. The VFD 105 may comprise a memory 402 that comprises computer-executable instructions that when executed, cause the processor 404 to facilitate an inflow of external air, into a second portion 105b of the VFD 105 housed in the second portion 108 of the enclosure 102, namely the portion of the VFD 105 comprising the one or more heat sinks 128 of the VFD 105 as shown in FIGS. 2-4. As previously disclosed, the one or more heat sinks 128 of the VFD 105 are positioned to extend from the internal divider 119 and into the compartment 110 of the second portion 108 of the enclosure 102. The instructions further cause the processor 404 to traverse the air through the second portion of the VFD 105 and over the one or more heat sinks 128 to facilitate an exit of the air from the second portion of the VFD 105, wherein the traversed air is isolated from one or more internal components 106 of the VFD 105 that are housed in a first portion 105a of the VFD 105 positioned within the first portion 104 of the enclosure 102, as shown in FIGS. 2-4. Further, the instructions cause the processor 404 to facilitate the flow of the air over one or more heat sinks 128 of the VFD 105 housed in the second portion 108 of the enclosure 102 and subsequently, facilitate the exit of the air flowing through the one or more heat sinks 128 from the second portion of the VFD 105.

Additionally, the VFD 105 may include an in-built microcontroller. An embedded microprocessor may govern the overall operation of the VFD controller. Basic programming of the microprocessor may be provided as user-inaccessible firmware. User programming of display, variable, and function block parameters may be provided to control, protect, and monitor components of the VFD 105 (e.g., motor, the driven equipment).

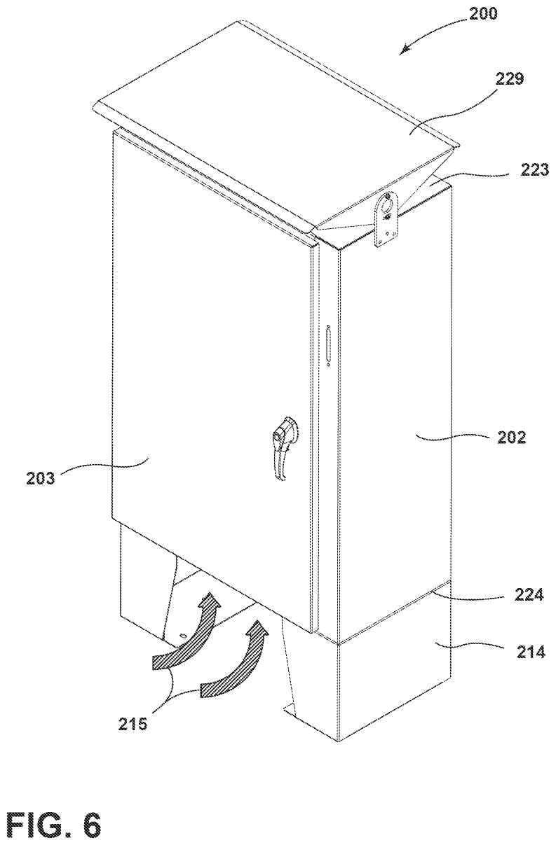

Referring now to FIGS. 6-17, a second exemplary configuration of the VFD apparatus 200 is shown. Where features of the second exemplary VFD apparatus 200 are the same or similar to those described above with respect to the VFD apparatus 100 of FIGS. 1A-5, the numbers are the same or similar.

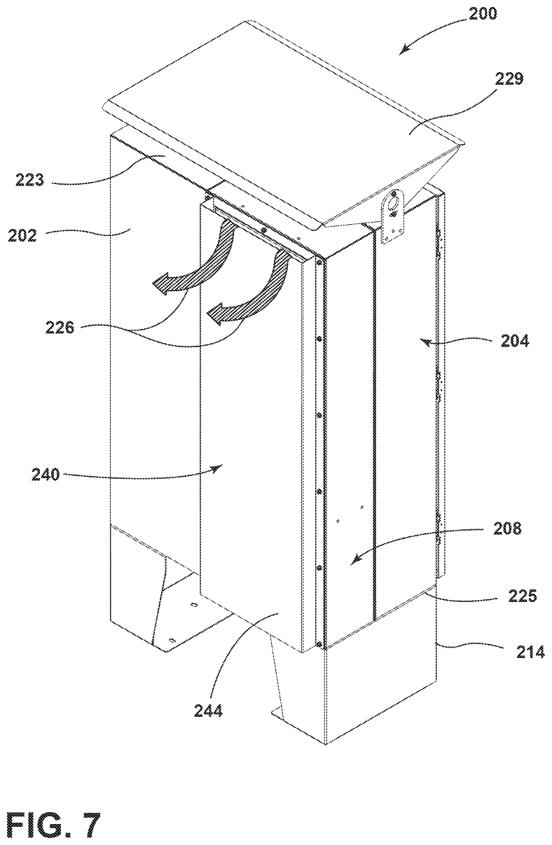

As shown in FIGS. 6-17, the VFD apparatus 200 is configured to allow the heat generated by heat sinks 228 of a VFD 205 during operation to be dispersed into the surrounding atmosphere by using only the VFD's integral cooling system (i.e., the heat sinks 228), as designed and equipped by the VFD manufacturer, and without the use of any additional fans to assist with the removal and dissipation of the heat. As shown in FIGS. 6 and 7, the VFD apparatus 200 may include an enclosure 202 having a first portion 204 and a second portion 208. A door 203 may be coupled with the enclosure 202 and configured to selectively close the first portion 204 of the enclosure 202 when in a closed position, as shown in FIG. 6.

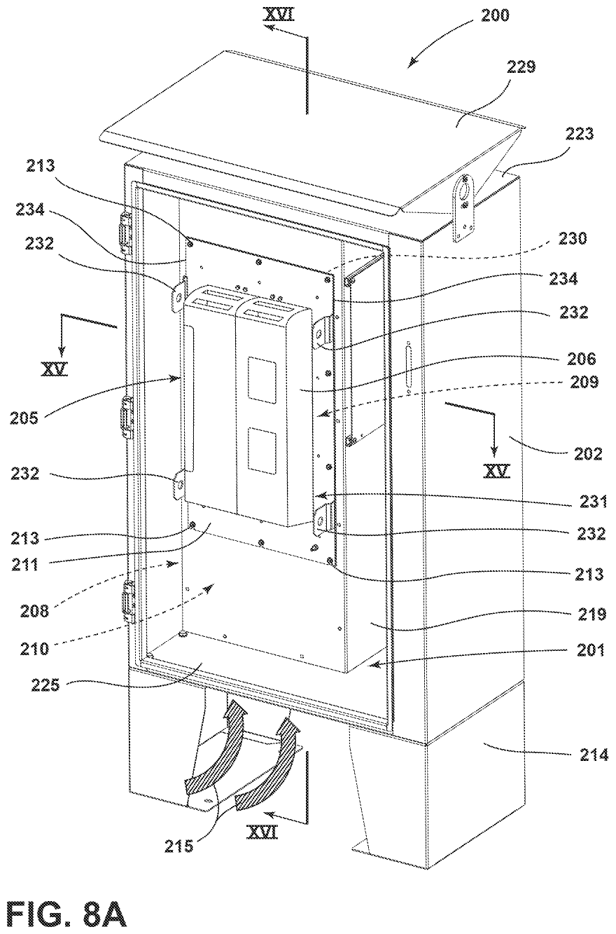

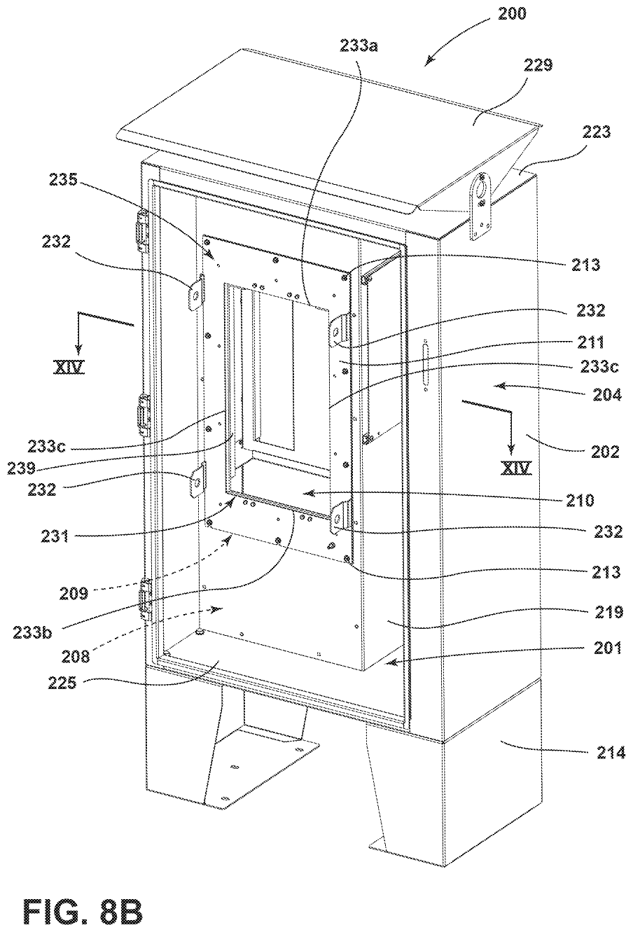

As best shown in FIGS. 6-8B, the VFD apparatus 200 includes the enclosure 202 having a lower wall 225 and an upper wall 223. The enclosure 202 further includes the first portion 204 defining a space 201 configured to house one or more internal electronic components 206 that are essential for the functioning of a VFD 205 (FIG. 8A). In other words, as shown in FIG. 8A, the enclosure 202 of the VFD apparatus 200 is configured such that one or more internal electronic components 206 of a VFD 205 are housed in a space 201 defined by the first portion 204 of the enclosure 202. These components 206 may include various electronic components such as, but not limited to, diodes, transistors, capacitors, resistors in any suitable combination depending on the design requirements of a VFD 205 housed by the enclosure 202. The one or more electronic components 206 of the VFD 205 may further include circuitry between components along with the components 206 themselves.

The enclosure 202 further includes the second portion 208 defining a compartment 210. The shape of the compartment 210 defined by the second portion 208 of the enclosure 202 may be a symmetrical geometric shape such as, but not limited to, a cuboidal, or a cylindrical shape. The cross-section of the compartment 210 defined by the second portion 208 may accordingly be circular, square, or rectangular or any other shape depending on the overall dimensions of the second portion 208 of the enclosure 202. In various examples, the dimensions of the second portion 208 and the compartment 210 may be varied within the design constraints of the enclosure 202. The dimensions of the second portion 208 may accordingly be varied to define the compartment 210 within the enclosure 202 based on design considerations as described above. In another example, the compartment 210 may be cylindrical. In yet another example, the shape of the compartment 210 may be conical with the diameter decreasing along the axis from one end to the other. The remaining volume, in both these examples, inside the enclosure 202 may be used for other components such as, but not limited to, an exhaust mechanism 222. In some examples, the shape and size of the compartment 210 may be predetermined depending on the design requirements and to achieve the objective of isolating the first and the second portions 204, 208 of the enclosure 202 of the VFD apparatus 200.

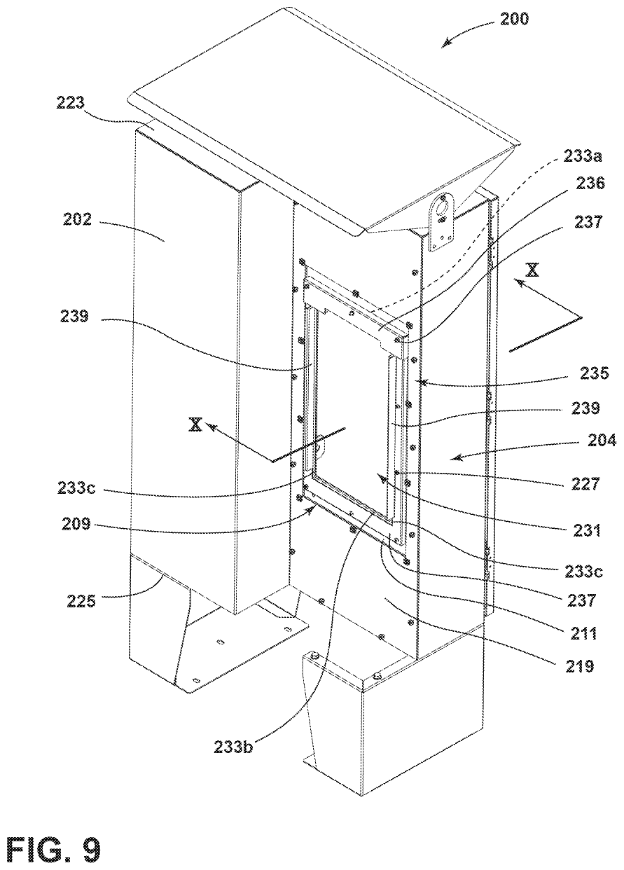

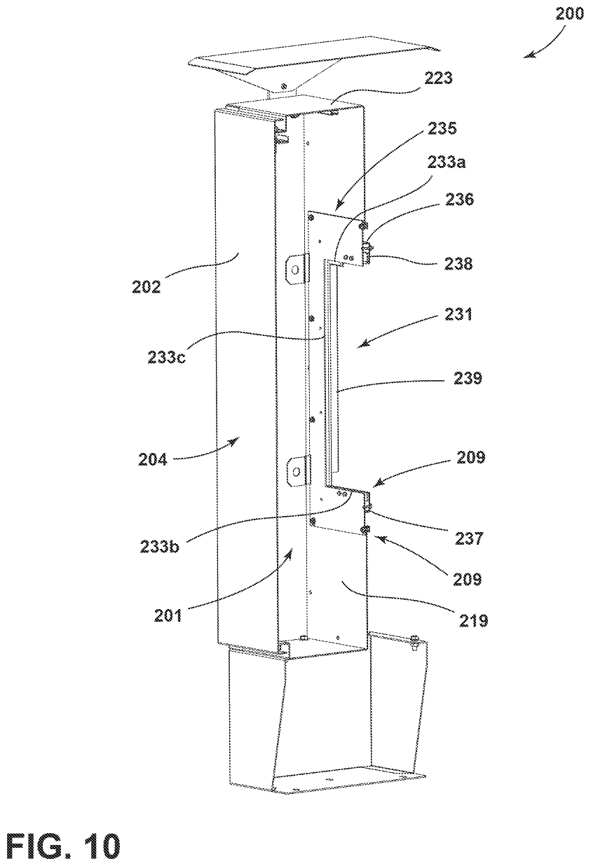

The first and second portions 204, 208 of the enclosure 202 are separated and isolated by an internal divider 219 which may be formed of one or more walls extending from the lower wall 225 of the enclosure 202 to the upper wall 223 of the enclosure 202. In various examples, the internal divider 219 may be coupled with one or both of the first and second portions 204, 208 of the enclosure 202. For example, the internal divider 219 may be welded to the enclosure 202 to separate and isolate the first portion 204 of the enclosure 202 from the second portion 208 of the enclosure 202. In other examples, the internal divider 219 may be integrally formed with one of the first and second portions 204, 208 of the enclosure 202 such that seam between the internal divider 219 and the enclosure 202 is sealed. For example, as shown in FIG. 9, the internal divider 219 may be integrally formed with the first portion 204 of the enclosure 202.

In various examples, the internal divider 219 may define an opening 209 configured to at least partially receive the VFD 205. In various examples, during assembly, the VFD 205 may be positioned through the opening 209 defined in the internal divider 219 such that the electrical components 206 of the VFD 205 are positioned within the space 201 defined by the first portion 204 of the enclosure 202 and one or more heat sinks 228 of the VFD 205 are positioned within the compartment 210 defined by the second portion 208 of the enclosure 202.

As shown in FIGS. 8B and 9, the opening 209 may be configured to be at least partially covered by a panel 211. The panel 211 may be coupled with the internal divider 219. For example, the panel 211 may be coupled with the internal divider 219 by a plurality of fasteners 213. The panel 211 and the internal divider 219 may be sealed with a gasket 230 extending about the entire circumference of the panel 211 such that the gasket 230 is pressed between the panel 211 and the internal divider 219 when the panel 211 is fully coupled with the enclosure 202 to improve the seal between the panel 211 and the internal divider 219 proximate the opening 209.

As best shown in FIG. 8A, the VFD 205 may be coupled with the panel 211. As previously discussed, the panel 211 may be operably coupled with the internal divider 219 using one or more fasteners 213 to at least partially cover the opening 209. The panel 211 may further define a receiving space 231 configured to at least partially align with the opening 209 of the internal divider 219. The receiving space 231 may be sized to accommodate the VFD 205 of the VFD apparatus 200. It will be understood that the size, shape, and configuration of the receiving space 231 and the panel 211 may be adjusted to accommodate other electronic components or VFD configurations without departing from the scope of the present disclosure.

In various examples, the panel 211 may be configured to provide access to the cooling fans and heatsinks 228 of the VFD 205 through the opening 209 of the internal divider 219. The panel 211 may have one or more flanges 232 extending outward from an outer perimeter edge 234 of the panel 211 and positioned perpendicular to the panel 211. Each of the one or more flanges 232 may be configured to allow for ease of installation of the panel 211 and the accompanying VFD 205 during assembly.

In various examples, the panel 211 may be part of a panel assembly 235. Where the panel 211 is part of a panel assembly 235, the panel assembly 235 may further include a first bracket 236 and a second bracket 237 configured to support one or more gaskets 238, 239, as shown in FIG. 9. The first bracket 236 may be configured to be positioned along an upper interior edge 233a of the receiving space 231 defined by the panel 211. The second bracket 237 may be a U-shaped bracket, as shown in FIG. 9, and may be configured to extend at least partially along a bottom interior edge 233b and opposing lateral interior edges 233c of the panel 211 defining the receiving space 231. As shown in FIG. 9, the first and second brackets 236, 237 may be coupled with the panel 211. For example, the first and second bracket 236, 237 may be coupled with the panel 211 using a plurality of fasteners 227.

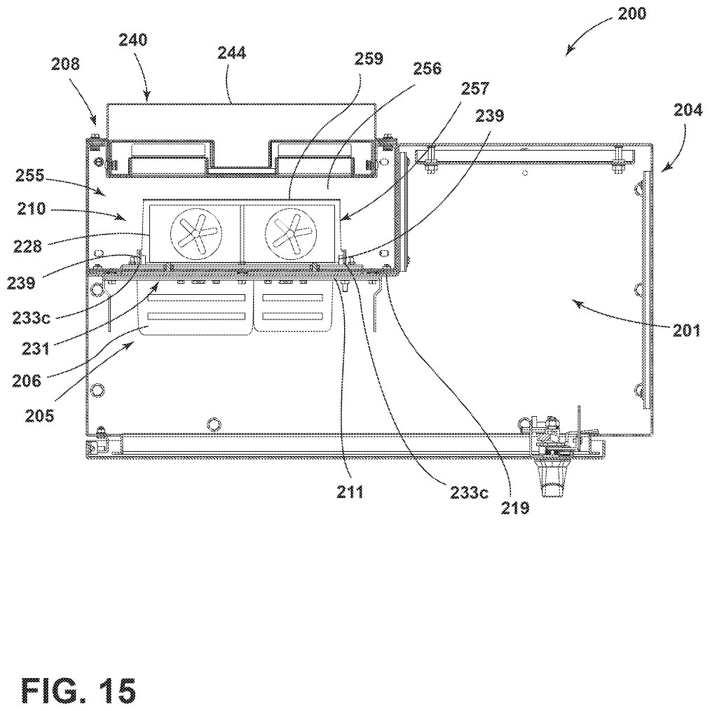

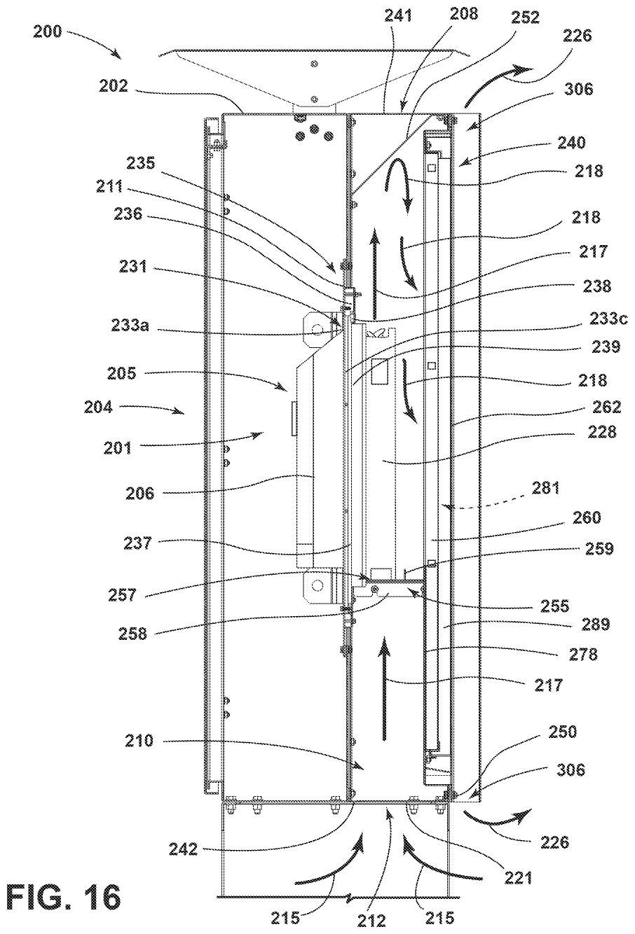

Each of the first and second brackets 236, 237 may be coupled with one or more gaskets 238, 239. In various examples, the gaskets 238, 239 may be high temperature silicone gaskets. For example, as shown in FIGS. 9 and 10, the first bracket 236 may extend at least partially over an upper gasket 238 positioned along the upper interior edge 233a of the receiving space 231, and the second bracket 237 may be coupled with a pair of opposing lateral gaskets 239 each extending along a respective lateral interior edges 233c of the receiving space 231. When the VFD 205 is installed within the receiving space, the upper gasket 238 and the pair of opposing lateral gaskets 239 are configured to abut the VFD 205 to provide a seal about the edge of the receiving space 231 of the panel 211 (FIGS. 15 and 16). The second portion 208 may be further configured such that air moving from the ingress 212 to the egress 220 is directed to flow over the one or more heat sinks 228 of the VFD 205. It will be understood that the configurations of brackets and gaskets is exemplary and that other configurations or combinations of brackets may be used to place one or more gaskets about the edges of the panel 211 to seal the space between the panel 211 and the VFD 205 without departing from the present disclosure.

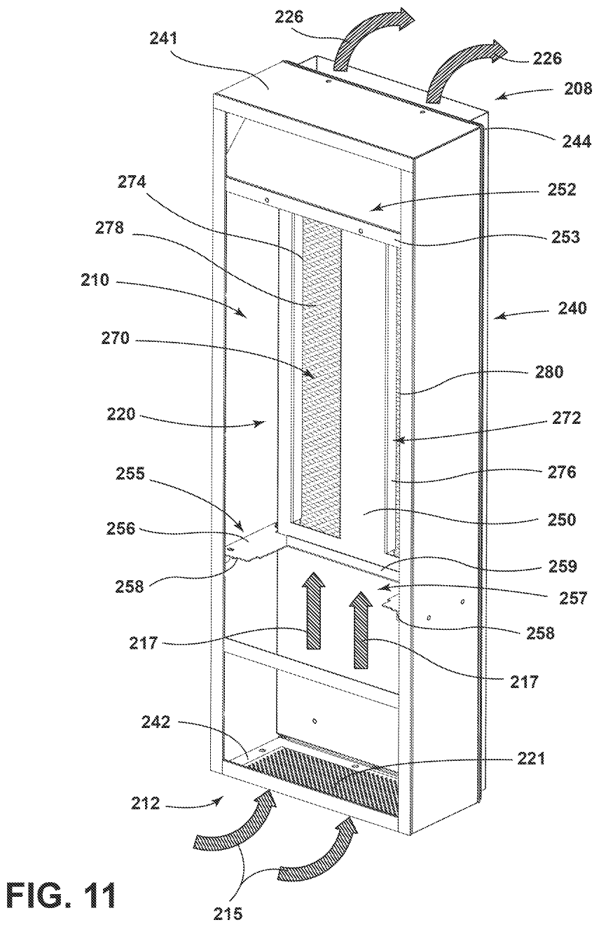

The second portion 208 of the enclosure 202 may be separable from the first portion 204 of the enclosure 202 in various examples. As shown in FIG. 11, the second portion 208 may be operably coupled with a vent assembly 240 and may include at least an upper wall 241, a lower wall 242, and a rear wall 250. It will be understood that any wall 241, 242, 250 of the second portion 208 may be integrally formed with or the same as the corresponding wall of the enclosure 202 without departing from the scope of the present disclosure. In other words, it is contemplated that the enclosure 202 may be configured such that the second portion 208 is not separable from the first portion 204 and is integrally formed with the first portion 204 and the internal divider 219.

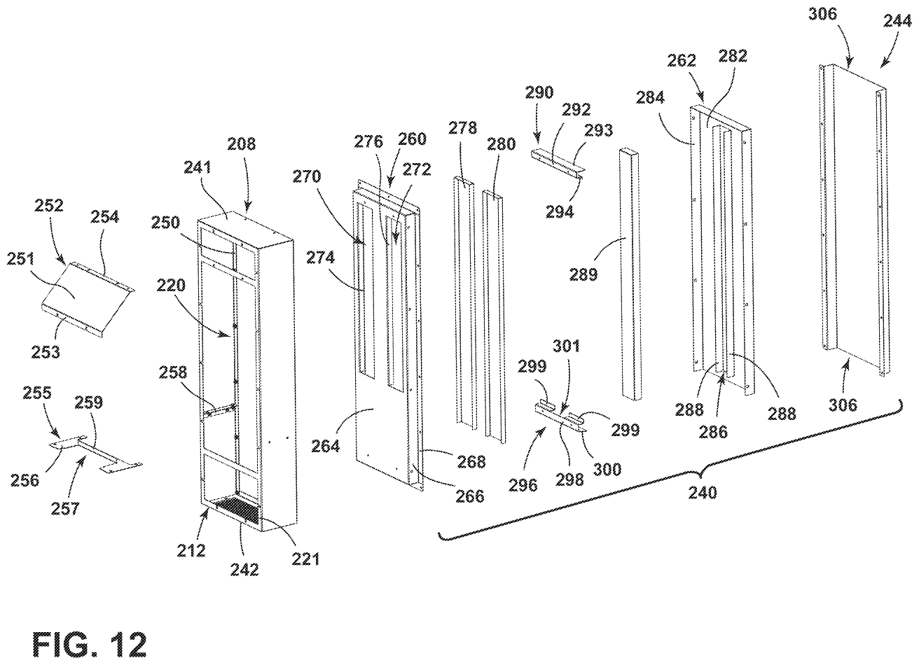

With reference now to FIGS. 11 and 12, the second portion 208 may be configured to define the ingress 212 and the egress 220 such that a vortex region, referred to herein as a vortex cooling tunnel (VCT) is formed within the compartment 210 as the heated air moves from the ingress 212 to the egress 220. The lower wall 242 of the second portion 208 may define the ingress 212 of the enclosure 202. As best shown in FIG. 11, a screen 221 may be positioned over the ingress 212 which is defined in communication with the compartment 210 of the second portion 208. The ingress 212 is configured for facilitating entry of air into the compartment 210. As best shown in FIG. 12, the rear wall 250 of the second portion 208 may define the egress 220 in communication with the compartment 210 and configured for facilitating an exit of the air from the compartment 210. In various examples, the vent assembly 240 may be selectively coupled with the rear wall 250 of the second portion 208 to extend over the egress 220.

The second portion 208 of the enclosure 202 may further include an inner deflector 252 positioned proximate the upper wall 241 of the second portion 208. The inner deflector 252 may include a body 251 positioned at an angle extending downward from the joint of the upper wall 241 and the rear wall 250 of the second portion 208 toward the internal divider 219, as shown in FIGS. 11-13A. As best shown in FIGS. 11 and 12, the inner deflector 252 may further include a front coupling flange 253 and a rear coupling flange 254. When the deflector 252 is installed within the compartment 210 of the second portion 208, the front coupling flange 253 may be configured to be operably coupled with the internal divider 219 and the rear coupling flange 254 may be configured to be operably coupled with the rear wall 250 of the second portion 208. As best shown in FIG. 16, the inner deflector 252 is configured to direct air that has flowed across the heat sinks 228 of the VFD 205 toward the egress 220 along the rear wall 250 of the second portion 208 of the enclosure 202, as described in more detail elsewhere herein.

As shown in FIGS. 11 and 12, the second portion 208 of the enclosure 202 may further include a baffle 255 positioned substantially parallel to and between the upper wall 241 and the lower wall 242 of the second portion 208 of the enclosure 202. The baffle 255 may be supported by one or more support brackets 258 extending along lateral walls 243 of the second portion 208. Each of the support brackets 258 may be coupled with the respective lateral wall 243. Accordingly, the one or more support brackets 258 may be positioned within the compartment 210 to extend from the rear wall 250 of the second portion 208 of the enclosure 202 toward the internal divider 219. In various examples, the baffle 255 and support brackets 258 may be positioned proximate the opening 209 defined by the internal divider 219 and/or the receiving space 231 defined by the panel 211 when the enclosure 202 is fully assembled.

As best shown in FIGS. 11 and 12, the baffle 255 may define an opening 257. In various examples, the opening 257 may be configured to at least partially receive the heat sinks 228 of the VFD 205 when the VFD 205 is installed within the enclosure 202 (FIG. 15), as discussed in more detail elsewhere herein. A flange 259 may extend upward from and substantially perpendicular to the body 256 of the baffle 255. The flange 259 may be positioned proximate the opening 257 and may be configured to guide insertion of the baffle 255 and the VFD 205 within the compartment 210 of the second portion 208. As discussed in more detail elsewhere herein, the baffle 255 may be formed to fit closely around the heat sink(s) 228 of the VFD 205, and the baffle 255 may be positioned to prevent airflow back toward the ingress 212 after the air passes over the heat sink(s) 228 of the VFD 205.

As shown in FIGS. 11-13, a vent assembly 240 may be coupled with the rear wall 250 of the second portion 208 of the enclosure 202. The vent assembly 240 may include an internal panel 260 and an external panel 262 with one or more screens 278, 280, 289 and/or deflectors 290, 296 positioned between the internal panel 260 and the external panel 262. As discussed in more detail elsewhere herein, the vent assembly 240 may be configured to facilitate the exit of the air out of the enclosure 202 through the egress 220. It is contemplated that the vent assembly 240 may be positioned in other positions on the enclosure 202 or may be adjusted in size or shape without departing from the scope of the present disclosure.

As previously introduced, the vent assembly 240 may include an internal panel 260 is sized to cover the egress 220 defined by the rear wall 250 of the second portion 208. With reference now to FIGS. 11-13, the internal panel 260 may include a body 264 and a perimeter lip 268. The perimeter lip 268 may extend around and be offset from the body 264 by a perimeter wall 266 such that the perimeter wall 266 is perpendicular to both the body 264 and the perimeter lip 268 and the perimeter lip 268 is substantially parallel to the body 264. The body 264 may be configured to be aligned with the egress 220 and may be at least partially received by the egress 220 in various examples. The perimeter lip 268 of the internal panel 260 may be configured to be coupled with the rear wall 250 of the second portion 208 of the enclosure 202. For example, the perimeter lip 268 of the internal panel 260 may be coupled with the second portion 208 by a plurality of fasteners, welding, or other methods of coupling. In other examples, the internal panel 260 maybe hingedly coupled with the rear wall 250 of the second portion 208 of the enclosure 202 such that the vent assembly 240 functions as a rear door assembly to provide access to the second portion 208 of the enclosure 202 and the heatsinks 228 and components contained therein. Where such a vent assembly 240 is coupled with the rear wall 250 of the second portion 208, the joint between the vent assembly 240 and the rear wall 250 (e.g., where the perimeter lip 268 of the internal panel 260 meets the rear wall 250) may be sealed using one or more gaskets (not shown).

Referring still to FIGS. 11-13, the body 264 of the internal panel 260 may define first and second slots 270, 272 spaced apart and extending at least partially along the length of the internal panel 260. For examples, as shown in FIG. 11, when the internal panel 260 is coupled with the second portion 208, the first and second slots 270, 272 extend from proximate the upper wall 241 of the second portion 208 toward the lower wall 242 of the second portion 208. In various examples, the first and second slots 270, 272 stop above the baffle 255. However, it is contemplated that the first and second slots 270, 272 could extend the length of the internal panel 260 in some examples without departing from the scope of the present disclosure.

Each of the first and second slots 270, 272 may be framed by a respective pair of laterally opposing flanges 274, 276 extending from the body 264 of the internal panel 260 in the same direction as the perimeter wall 266. In other words, the first pair of laterally opposing flanges 274 and the second pair of laterally opposing flanges 276 may be parallel with the perimeter wall 266 and substantially perpendicular to the body 264 and the perimeter lip 268. It will be understood that the internal panel 260 defining first and second slots 270, 272 is exemplary and that, in some examples, a single slot or more than two slots may be defined by the internal panel 260 without departing from the scope of the present disclosure. It is further contemplated that the location and size of these slots may be adjusted to account for size and shape of the enclosure 202 and the VFD 205.

As shown in FIGS. 12-14, a first screen 278 is positioned to cover the first slot 270, and a second screen 280 is positioned to cover the second slot 272. In various examples, as shown in FIGS. 12, each of the first and second screens 278, 280 may have a U-shaped cross section. The U-shaped cross section is configured to allow the first and second screens 278, 280 to fit over and couple with the respective pair of laterally opposing flanges 274, 276 to cover the respective slot 270, 272. The screens 278, 280 are configured to prevent bugs, insects, and animals from moving through the slots 270, 272.

The external panel 262 is configured to be coupled with the internal panel 260 and includes a body 282 and a perimeter wall 284. The body 282 of the external panel 262 is configured to be aligned with the body 264 of the internal panel 260, and the perimeter wall 284 of the external panel 262 is configured to be at least partially received by the internal panel 260 to align with the perimeter wall 266 of the internal panel 260. Together, the internal panel 260, the external panel 262, the perimeter wall 266 of the internal panel 260, and the perimeter wall 284 of the external panel 262 define a channel 281 through which air can flow through the egress 220, as described in more detail elsewhere herein. In various examples, the internal panel 260 and the external panel 262 may be coupled using fasteners. However, it is contemplated that the internal panel 260 and the external panel 262 may be coupled using other means including but not limited to welding or adhesive without departing from the scope of the present disclosure.

The body 282 of the external panel 262 defines a central slot 286 extending at least partially along the length of the body 282. In various examples, the central slot 286 may be the same length as the first and second slots 270, 272 of the internal panel 260. In other examples, the central slot 286 may be longer than the first and second slots 270, 272 and/or may extend the full length of the external panel 262. Extending the central slot 286 the full length of the external panel 262 may provide additional area through which airflow can exit the vent assembly 240. It will be understood that the external panel 262 defining a single central slot 286 is exemplary and that, in some examples, the external panel 262 may define a plurality of slots without departing from the scope of the present disclosure. It is further contemplated that the location, length, and size of these slots may be adjusted to account for size and shape of the enclosure 202 and the VFD 205.

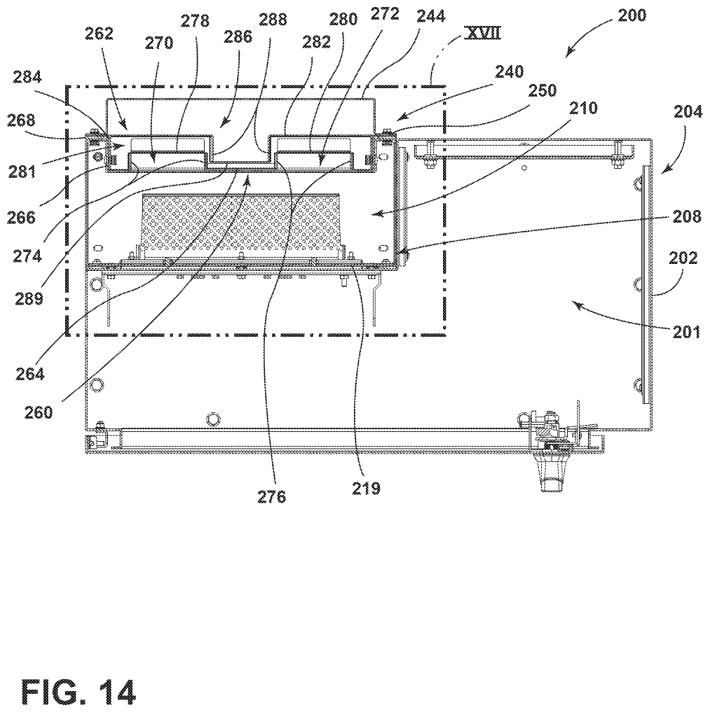

The central slot 286 is at least partially framed by a third pair of laterally opposing flanges 288 extending length wise along the slot 286. The third pair of laterally opposing flanges 288 is formed to extend outward from the body 282 of the external panel 262 in the same direction as the perimeter wall 284 of the external panel 262. In other words, the third pair of laterally opposing flanges 288 may be parallel with the perimeter wall 284 of the external panel 262 and substantially perpendicular to the body 282 of the external panel 262. As best shown in FIGS. 11 and 14, the third screen 289 is positioned over the central slot 286. The third screen 289 may have a U-shaped cross section and may be configured to fit over and couple with the third pair of laterally opposing flanges 288 framing the central slot 286. Like the first and second screens 278, 280, the third screen 289 may be configured to prevent bugs, animals, and other foreign objects from entering the compartment 210 via the channel 281 of the vent assembly 240.

As best shown in FIG. 14, when the vent assembly 240 is assembled, the first and second pairs of laterally opposing flanges 274, 276 extend from the body 264 of the internal panel 260 and into the channel 281 toward the external panel 262. The third pair of laterally opposing flanges 288 is positioned between the first and second pairs of laterally opposing flanges 274, 276 of the internal panel and is configured to extend toward the body 264 of the internal panel 260 when the vent assembly 240 is assembled. Each of the pair of laterally opposing flanges 274, 276, 288 extends from the respective panel 260, 262 into the channel 281 to guide airflow through the channel 281, as described in more detail elsewhere herein. It will be understood that additional flanges, baffles, or deflectors may be included within the channel 281 without departing from the scope of the present disclosure.

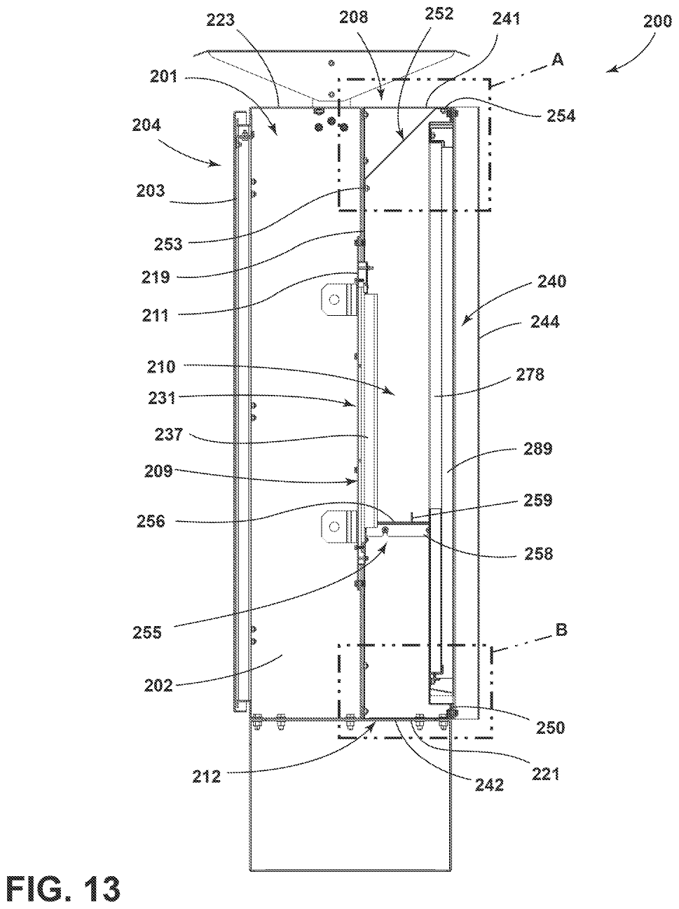

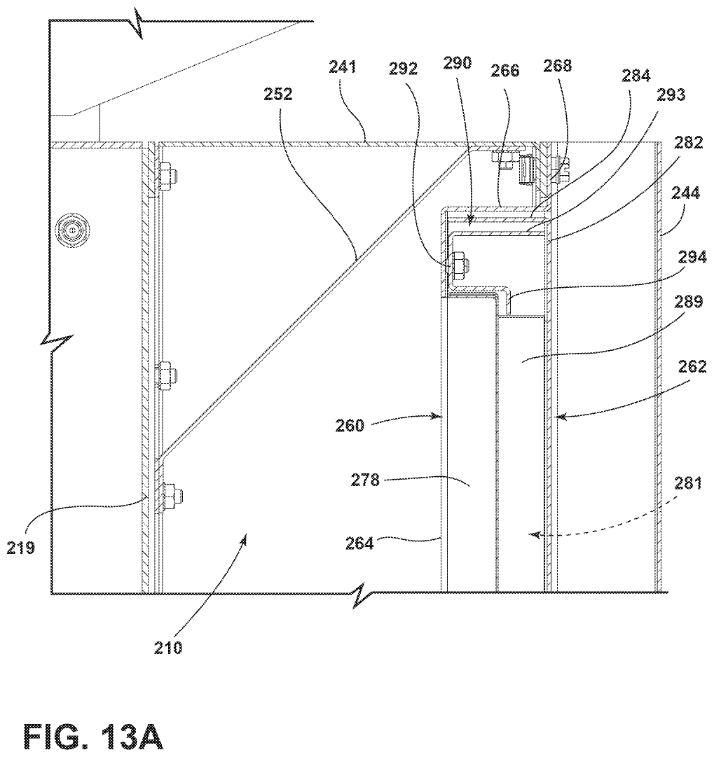

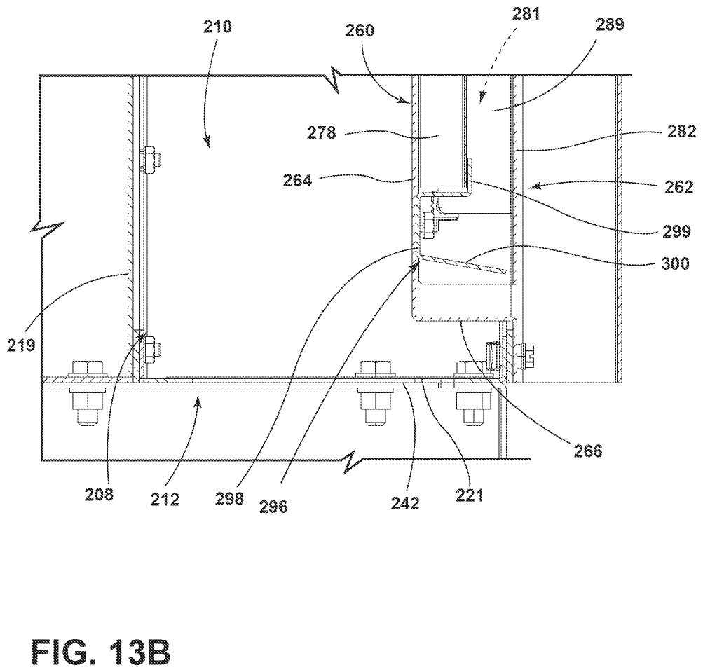

As shown in FIG. 14, the coupling of the internal panel 260 with the external panel 262 is configured to at least partially enclose the channel 281 of the vent assembly 240 to allow air to pass through the egress 220 and the vent assembly 240 but prevent water from entering into the channel 281 and, subsequently, the compartment 210. To further ensure that water cannot enter the channel 281 through the ends of the channel 281, one or more deflectors 290, 296 may be positioned between the internal panel 260 and the external panel 262 at the ends of the channel 281, as shown in FIGS. 12-13B. As best shown in FIG. 13A an upper deflector 290 may include a main portion 292 configured to be coupled with the body 264 of the internal panel 260 proximate the upper portion of the perimeter wall 266 of the internal panel 260. A lip 293 may extend from the main portion 292 and may be configured to cover ends of the first and second screens 278, 280. A deflecting flange 294 may extend from the opposite end of the body from the lip 293 and may be configured to be aligned with the perimeter walls 266, 284 of the internal and external panels 260, 262. As best shown in FIG. 13B, a lower deflector 296 may be include a main portion 298 configured to be coupled with the body 264 of the internal panel 260 proximate the upper portion of the perimeter wall 266 of the internal panel 260. A lip 299 may extend from the main portion 298 and may be configured to cover ends of the first and second screens 278, 280. In various examples, the lip 299 may be formed of a single continuous flange or may define a central space 301 such that each of the first and second screens 278, 280 is covered separately. A deflecting flange 300 may extend from the opposite end of the body from the lip 299 and may be angled to extend downward from the main portion 298 toward the perimeter walls 266, 284 of the internal and external panels 260, 262 and the body 282 of the external panel 262.

In various examples, the VFD apparatus 200 may further include a rear shield 244 positioned over the vent assembly 240 and offset from the external panel 262 to allow airflow between the shield 244 and the external panel 262. The rear shield 244 may be coupled with the rear wall 250 of the second portion 208 of the enclosure 202 or may be otherwise coupled with the enclosure 202 to cover the vent assembly 240. In other examples, the VFD apparatus 200 may include a sun shield 229 operably coupled with the upper wall 223 of the enclosure 202. It will be understood that the rear shield 244 and the sun shield 229 are optional and may be used separately, together, or not at all.

As previously discussed, the enclosure 202 is configured such that the first portion 204 of the enclosure 202 houses the one or more internal electronic components 206 and is isolated from the second portion 208 that defines the compartment 210. For example, the first portion 204 of the enclosure 202 may be separated and isolated from the second portion 208 of the enclosure and the compartment 210 defined therein by an internal divider 219. This prevents the external air that enters the compartment 210 from exterior of the enclosure 202 through the ingress 212 of the compartment 210 from flowing through the isolated first portion 204 of the enclosure 202, thereby, protecting the components 206 from contaminants that may be present in the external air.

In various examples, the compartment 210 of the second portion 208 may be configured such that the airflow through the compartment 210 is achieved/facilitated in a manner similar to a vortex region as understood in the context of fluid dynamics. For instance, the airflow velocity may be greatest next to an axis X of the cooling tunnel or compartment 210 and may decrease in inverse proportion to the distance from the axis X. For instance, the distribution of velocity and vorticity (i.e., the curl of the flow velocity), as well as the concept of circulation, may be used to characterize the airflow forming a vortex region through the cooling tunnel. The heat generated by the heat sink(s) 228 of the VFD 205 along with the integral cooling system of the VFD 205 creates a vortex type condition that enhances the upward movement of the air through the compartment 210. However, the mere naming convention does not restrict any design changes to the VFD apparatus 200, the enclosure 202, the compartment 210, or any other features of the apparatus 200 that may be made according to the implementation requirements. It may be appreciated that various shapes, sizes, dimensions, and cross sections are envisaged which may or may not lead to vortex-like characteristics in the airflow through the cooling tunnel without departing from the scope of the ongoing disclosure.

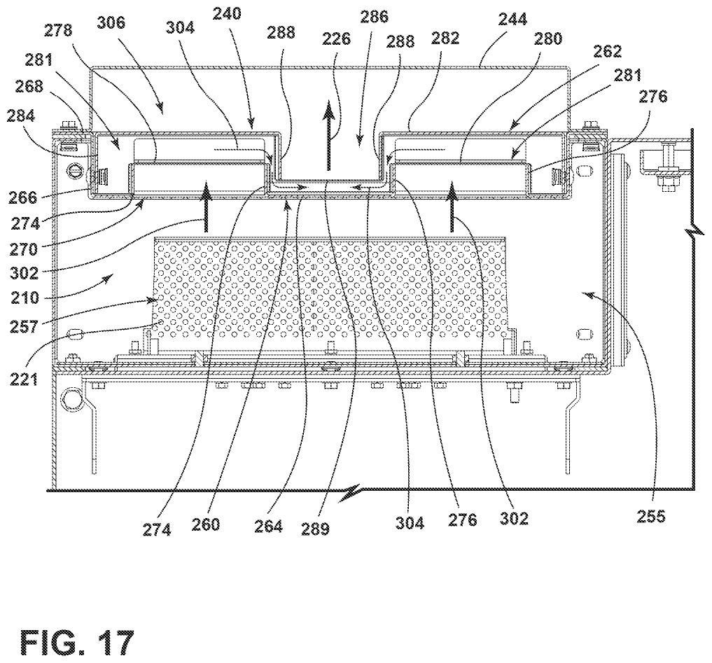

As shown in FIGS. 16 and 17, and as previously introduced, the second portion 208 of the enclosure 202 may define the ingress 212 through which external air enters the compartment 210 as shown by arrows 215. The position of the ingress 212 may be predetermined by the manufacturer and is not limited by the present disclosure. For example, the ingress 212 may be located either on one or more sides of the enclosure 202 or proximate the upper wall 223 of the enclosure 202 depending on the design requirements and safety considerations. Additionally, the shape and size of the ingress 212 may be predetermined such that it is optimal to facilitate the inflow of air but restricts the inflow of insects or foreign contaminants.

The airflow path illustrated by arrows 215 directs ambient air into the compartment 210. The ambient air may include one or more foreign objects such as, but not limited to, dirt particles, moisture, insects and other contaminants. Such foreign objects are restricted from entering the first portion 204 of the enclosure 202 by isolation of the compartment 210 of the second portion 208 through which the external air flows, protecting the internal electronic components 206 of the VFD 205 and any associated circuitry of these components 206 for exposure to the foreign objects. This objective is achieved by isolating the compartment 210 from the first portion 204 of the enclosure 202 that houses these internal electronic components 206 and any associated circuitry. Additionally, as previously introduced, the screen 221 may be installed on the ingress 212 to restrict the flow of contaminants into the compartment 210.

Once the air enters the compartment 210 of the second portion 208 through the ingress 212, it flows through the compartment 210 along an air flow path such as the path indicated by arrows 217. As shown in FIGS. 16 and 17, air from the ingress 212 is directed across the heat sinks 228 by the body 256 of the baffle 255, traveling through the receiving space 257 of the baffle 255 and across the heat sinks 228 of the VFD 205. The heat generated from the internal components 206 during their operation is dissipated into the air traversing across the heat sinks 228. Thus, the heat is not allowed to damage the components 206 of the VFD 205 located in the first portion 204 of the enclosure 202. In various examples, the heat sinks 228 may be located at a predetermined distance that is close enough to the egress 212 to absorb as much heat as possible. However, this distance can vary depending on design requirements.

The airflow then flows upward and is deflected rearward and downward toward the vent assembly 240 by the inner deflector 252. Specifically, the inner deflector 252 directs the air flowing along arrows 218 downward and toward egress 220 defined by the rear wall 250 of the second portion 208 and the vent assembly 240 aligned with the egress 220. Airflow then moves along the rear wall 250 as shown by arrows 218 and exits through the egress 220 via the vent assembly 240. As previously introduced and as shown in FIG. 15, the baffle 255 is formed to fit closely around the vent assembly 240 and the heat sinks 228 of the VFD 205 to prevent airflow back toward the ingress 212. The baffle 255 is installed near the bottom of the heat sink(s) 228 of the VFD 205 to prevent the air from possibly circulating inside the compartment 210. This prevention of circulation forces the heated air to flow through the egress 220 via the slots 270, 272, 286 and channel 281 of the vent assembly 240.

With continued reference to FIGS. 15 and 16, the lateral gasket 239 and the upper gasket 238 of the panel assembly 235 seal the receiving space 221 of the panel 211 to prevent any airflow between the compartment 210 and the space 201 through the receiving space 221. As best shown in FIG. 15, the lateral gasket 239 are pressed against the heat sink(s) 228 of the VFD 205 to seal the lateral edges 233c, 233c of the receiving space 221. As shown in FIG. 16, the upper gasket 238 abuts the top of the heat sink(s) 228 to prevent airflow through the receive space 221 of the panel 211 at the upper interior edge 233a. The contributes to the full separation of the first and second portions 204, 208 of the enclosure 202 by the internal divider 219.

The vent assembly 240 may be configured to facilitate the exit of the air out of the compartment 210 via the egress 220. As best shown in FIG. 17, the heated air flows from the compartment 210 through the egress 220 and the vent assembly 240. In particular, the heated air flows through the first and second slots 270, 272 of the internal panel 260 of the vent assembly 240 along the airflow path shown by arrows 302. The heated air enters the channel 281 defined by the internal panel 260 and the external panel 262 and flows through the channel 281 along airflow paths shown by arrows 304 to the central slot 286 of the external panel 262. The pairs of laterally opposing flanges 274, 276, 288 direct the air through the central slot 286 and out of the channel 281, as shown by the airflow path along arrows 226. Where a rear shield 244 is installed, the air then flows up or down and outward of end openings 306 of the rear shield 244, as shown by arrows 226 in FIG. 16. This allows the heated air to exit the compartment 210 of the second portion 208 without circulating back toward the ingress 212 or exposing the electrical components 206 of the VFD 205 located in the first portion 204 of the enclosure 202 to the heated air, cooling the VFD 205 while maintain the necessary ratings, as discussed in more detail elsewhere herein.

For additional stability, in various examples, the enclosure 202 may comprise an enclosure stand 214 that may include two or more legs to support the enclosure 202. In other examples mounting adapters (not shown) may be used to mount the VFD apparatus 200 on an external periphery or a device such as an electronic motor. It is further contemplated that the VFD apparatus 200 may be configured to be mounted along a wall or other surface and may include a mount (not shown) for such configuration without departing from the scope of the present disclosure.

Referring now to FIGS. 1A-17, it will be understood that any of the enclosures 102, 202 disclosed herein may be fabricated with additional cooling compartments 110, 210 to accommodate the installation of multiple VFD's in the same enclosure 102, 202. The overall size of the enclosure 102, 202 and the size of the cooling compartment 110, 210 and/or electrical components compartment 106, 206 can be adjusted to accommodate the size or quantity of components 106, 206 or heat sinks 128, 228 to be installed in the enclosure and/or each compartment.

Each exemplary apparatus 100, 200 disclosed herein is configured to provide a degree of protection to personnel against access to hazardous parts and satisfies different environmental conditions unique to the application. In various embodiments, and as described in more detail below, the compartment 110 of the VFD apparatus 100 may be rated as National Electrical Manufacturers Association (NEMA) 3R or NEMA 3RX as defined by NEMA 250-2018 published by NEMA in 2018 (hereinafter referred to as “NEMA 250-2018”). Similar, the compartment 210 of the VFD apparatus 200 may be rated as NEMA 1, NEMA 3R, or NEMA 3RX as defined by the NEMA 250-2018. A VFD apparatus 100, 200 as described herein having a NEMA 3R rating may be better suited for outdoor applications and rainfall. The first portion 104 of the enclosure 102 of the VFD apparatus 100 that is isolated from the second portion 108 and the compartment 110 defined thereby may be rated as NEMA 1, NEMA 3R or NEMA 3RX as defined by the NEMA 250-2018. In contrast, the first portion 204 of the enclosure 202 of the VFD apparatus 200 may be rated as NEMA 1, NEMA 3R, NEMA 3RX, NEMA 4, NEMA 4X, or NEMA 12 as defined by the NEMA 250-2018. In both the VFD apparatus 100 and the VFD apparatus 200, the second portion 108, 208 may be rated as NEMA 1, 3R, 3RX. In the exemplary apparatus 100, 200 the need for additional fans, filters, or an air conditioner may also be eliminated by isolating the heat that is generated from the watt loss from the other components 106, 206 of the VFD 105, 205. This eliminates outside air from flowing through the isolated first portion 104, 204 of the enclosure 102, 202, thus protecting the components 106, 206 from contaminants. The features described elsewhere herein which allow the compartment 110, 210 to achieve these, and other similar, ratings are configured to allow the enclosure 102 to be suitable for most outdoor applications, and enclosure 202 to be suitable for most indoor and outdoor applications.

The apparatus 100 shown in FIGS. 1A-5 is configured for indoor or outdoor use. When used indoors, it provides a degree of protection to personnel against access to hazardous parts and also provides a degree of protection for all components, including electrical components 106, inside the first portion 104 of the enclosure 102 against ingress of solid foreign objects such as falling dirt. In addition to these protections, when used for outdoor applications, the VFD apparatus 100 provides a degree of protection with respect to the harmful effects on the VFD 105 due to the ingress of water caused by rain, snow, or sleet. The enclosure 102 may be constructed of stainless steel to provide additional corrosion resistance.

The apparatus 200 shown in FIGS. 6-17 is constructed for indoor or outdoor use to provide a degree of protection to personnel against access to hazardous parts; to provide a degree of protection for the components 206 inside the first portion 204 of the enclosure 202 against ingress of solid foreign objects such as falling dirt, windblown dust, circulating dust, lint, fibers, and flyings; to provide a degree of protection with respect to the harmful effects on the equipment due to the ingress of water caused by rain, snow, sleet, dripping, splashing, and hose directed water; and that will be undamaged due to the external formation of ice on the enclosure. The second portion 208 of the enclosure 202 similarly provides a degree of protection to personnel against access to hazardous parts, against ingress of solid foreign objects such as falling dirt, and against ingress of rain, snow, and sleet. When protection of the second portion 208 of the enclosure 202 against ingress of hose directed water is needed (e.g., where a NEMA rating other than 3R or 12 is desired or needed), the additional rear shield 244 (as shown in FIG. 7) may be installed over the egress 220 and/or the rear ventilation system 240 and the ingress 212 and/or air intake area as needed. An optional sun shield 229 is available when used outdoors for enhanced protection against heat gain due to direct sun exposure. As shown in FIG. 6, the sun shield 229 may be operably coupled with the upper wall 223 of the enclosure 202. By design, the cooling compartment 210 provides free air flow through that compartment 210, so the VFD heat sink 228 will be exposed to any contaminants freely floating in the air that could be upwardly drawn into this compartment 210. Accordingly, the screen 221 may be installed to reduce or eliminate such ingress. Otherwise, all components in enclosure 202 are fully protected against all exposure to water damage by falling or splashing water. The enclosure 202 may be constructed of stainless steel to provide additional corrosion resistance.

The advantages of the proposed embodiments and designs include elimination/prevention of outside air from flowing through the second portion 108, 208 of the enclosure 102, 202 protecting the components 106, 206 from contaminants. In addition, the space required inside the enclosure 102, 202 to sufficiently cool the VFD 105, 205 is reduced and the compartment 110, 210 or the second portion 108, 208 of the enclosure 102, 202 results in more efficient cooling of the VFD 105, 205.

In further accordance with the embodiments of this disclosure, a method for cooling the VFD 105, 205, is disclosed herein. The method comprises facilitating an inflow of air as shown by arrows 115, 215, through an ingress 112, 212, into a compartment 110, 210 (e.g., the VCT) housed in a second portion 108, 208 of an enclosure 102, 202 of the VFD apparatus 100, 200 The method further comprises traversing the entered air through the compartment 110, 210 to facilitate an exit of the air through an egress 120, 220. The traversed air is isolated from one or more internal components 106, 206 housed in a space 101, 201 defined by a first portion 104, 204 of the enclosure 102, 202. The method further comprises facilitating the flow of the air shown by arrows 117, 217 over one or more heat sinks 128, 228 housed in compartment 110, 210 of the second portion 108, 208 of the enclosure 102, 202 and subsequently, facilitating the exit of the air flowing outward of the enclosure 102, 202 through the egress 120, 220 along arrows 126, 226.

The terms “comprising,” “including,” and “having,” as used in the claims and specification herein, shall be considered as indicating an open group that may include other elements not specified. The terms “a,” “an,” and the singular forms of words shall be taken to include the plural form of the same words, such that the terms mean that one or more of something is provided. The term “one” or “single” may be used to indicate that one and only one of something is intended. Similarly, other specific integer values, such as “two,” may be used when a specific number of things is intended. The terms “preferably,” “preferred,” “prefer,” “optionally,” “may,” and similar terms are used to indicate that an item, condition, or step being referred to is an optional (not required) feature of the invention.

The invention has been described with reference to various specific and preferred embodiments and techniques. However, it should be understood that many variations and modifications may be made while remaining within the spirit and scope of the invention. It will be apparent to one of ordinary skill in the art that methods, devices, device elements, materials, procedures, and techniques other than those specifically described herein can be applied to the practice of the invention as broadly disclosed herein without resort to undue experimentation. All art-known functional equivalents of methods, devices, device elements, materials, procedures, and techniques described herein are intended to be encompassed by this invention. Whenever a range is disclosed, all subranges and individual values are intended to be encompassed. This invention is not to be limited by the embodiments disclosed, including any shown in the drawings or exemplified in the specification, which are given by way of example and not of limitation.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

All references throughout this application, for example patent documents including issued or granted patents or equivalents, patent application publications, and non-patent literature documents or other source material, are hereby incorporated by reference herein in their entireties, as though individually incorporated by reference, to the extent each reference is at least partially not inconsistent with the disclosure in the present application (for example, a reference that is partially inconsistent is incorporated by reference except for the partially inconsistent portion of the reference).

We hereby claim:

1. A variable frequency drive (VFD) apparatus, comprising:
an enclosure including a first portion and a second portion, wherein the first portion is isolated from the second portion by an internal wall;
one or more internal components coupled with the internal wall and at least partially housed in a space defined by the first portion of the enclosure; and
a compartment defined by the second portion of the enclosure, wherein the second portion further defines an ingress and an egress, the ingress defined in communication with the compartment and configured to direct air from outside of the enclosure into the compartment, wherein heat from the one or more internal components is dissipated by the air, and heated air is directed out of the compartment through the egress, and further wherein the heated air moving toward the egress and the air directed into the compartment through the ingress are configured to generate a vortex region moving through the compartment.

2. The apparatus of claim 1, further comprising one or more heat sinks operably coupled with the one or more internal components and positioned within the compartment, wherein the ingress is configured to direct air over the one or more heat sinks, and further wherein the second portion of the enclosure is configured to isolate air flowing through the compartment and over the one or more heat sinks from the one or more internal components housed in the space defined by the first portion.

3. The apparatus of claim 1, wherein the compartment has a National Electrical Manufacturers Association (NEMA) rating comprising one of 3R and 3RX.

4. The apparatus of claim 1, wherein the compartment has a NEMA rating comprising one of 1, 3R and 3RX.

5. The apparatus of claim 1, wherein the first portion has a NEMA rating comprising one of 1, 3R, 3RX, 4, 4X, and 12.

6. The apparatus of claim 1, wherein the compartment has a shape selected from a group consisting of a sphere, a cylinder, or a cube.

7. The apparatus of claim 1, further comprising a sieve positioned over the ingress and/or egress.

8. The apparatus of claim 1, wherein the ingress is defined proximate a lower wall of the enclosure or on one or more sides of the enclosure.

9. The apparatus of claim 1, further comprising an exhaust mechanism associated with the egress, placed on one or more sides of a hood of the enclosure, and wherein the exhaust mechanism facilitates an exit of the air from the compartment.

10. The apparatus of claim 1, further comprising one of an enclosure stand and a mounting bracket to support the enclosure.

11. A method of cooling a variable frequency drive (VFD), the method comprising:
defining a space within an internal divider, wherein the space is configured to at least partially receive one or more electrical components and one or more heat sinks;
positioning the internal divider within an enclosure to define a first portion of the enclosure and a second portion of the enclosure such that the first portion is isolated from the second portion by the internal divider;
positioning the one or more electrical components within the space of the internal divider such that the one or more electrical components are positioned within the first portion of the enclosure and the one or more heat sinks are positioned in the second portion of the enclosure;
facilitating an inflow of air from outside of the enclosure, through an ingress defined by an exterior wall of the second portion and into a compartment housed in the second portion of the enclosure;
traversing the ambient air through the compartment;
directing the air such that heat from the one or more heat sinks is dispersed by the air and at least part of the air becomes heated air; and
facilitating an exit of the heated air through an egress defined at an upper portion of the second portion of the enclosure, wherein the air is isolated from one or more internal components housed in the first portion of the enclosure.

12. An apparatus for housing and cooling a VFD, comprising:
an enclosure including a first portion defining a space and a second portion defining a compartment, wherein the enclosure further includes an upper wall and a lower wall;
an internal divider extending between the upper wall and lower wall of the enclosure and defining an opening;
a VFD positioned within the opening of the internal divider, wherein a heat sink of the VFD is positioned within the compartment;
a panel coupled with the VFD and further coupled with the internal divider, the panel including a gasket configured to seal the panel and the internal divider, wherein the first portion is isolated from the second portion by the internal divider and the panel;
an ingress defined by the second portion of the enclosure and in communication with the compartment; and
an egress defined by the second portion of the enclosure and in communication with the compartment, wherein the ingress and the egress are configured to direct air from external of the enclosure through the ingress, over the heat sink of the VFD, and outward of the enclosure through the egress.

13. The apparatus of claim 12, wherein electronic components of the VFD are positioned within the space defined by the first portion of the enclosure.

14. The apparatus of claim 12, wherein heat from the electronic components of the VFD is dissipated by the air directed over the heat sink of the VFD to create heated air to be directed outward of the enclosure.

15. The apparatus of claim 12, wherein the egress is defined by a rear wall of the second portion of the enclosure.

16. The apparatus of claim 12, further comprising a vent assembly, the vent assembly including:
an interior panel defining a first slot;
a screen positioned over the first slot;
an exterior panel defining a second slot, the interior panel and the exterior panel configured to define a channel extending between the first slot and the second slot, wherein air flow is directed from the compartment through the first slot, through the channel, and through the second slot to exit the compartment.

17. The apparatus of claim 16, further comprising:
a rear cover coupled with the second portion of the enclosure and configured to at least partially cover the second slot.

18. The apparatus of claim 12, wherein the internal divider is integrally formed with the first portion of the enclosure.

19. The apparatus of claim 12, further comprising:
a baffle positioned within the compartment and positioned proximate the heat sink of the VFD, the baffle configured to prevent airflow from the compartment toward the ingress.

20. The apparatus of claim 12, further comprising:
a gasket operably coupled with the panel, wherein the gasket is configured to abut the heat sink of the VFD.
